(19) United States
(12) Patent Application Publication
(10) Pub. No.: US 2026/0004991 A1
(43) Pub. Date: Jan. 1, 2026

(54) SYSTEMS AND METHODS OF ENERGY DISCRIMINATION OF BACKSCATTERED CHARGED-PARTICLES

(71) Applicant: ASML Netherlands B.V., Veldhoven (NL)

(72) Inventors: Xiaoyu JI, San Jose, CA (US); Weiming REN, San Jose, CA (US)

(73) Assignee: ASML Netherlands B.V., Veldhoven (NL)

(21) Appl. No.: 19/134,781

(22) PCT Filed: Nov. 1, 2023
(86) PCT No.: PCT/EP2023/080449

§ 371 Date: Jun. 2, 2025

Related U.S. Application Data
(60) Provisional application No. 63/429,684, filed on Dec. 2, 2022.

(51) Int. Cl. H01J 37/244; H01J 37/28

(52) U.S. Cl. CPC H01J 37/244; H01J 37/28; H01J 2237/24475

(57) ABSTRACT

Systems and methods of imaging a sample using a charged-particle beam apparatus are disclosed. The charged-particle beam apparatus may include a charged-particle source configured to generate primary charged particles, the primary charged particles forming a primary charged-particle beam along a primary optical axis, and a charged-particle detector comprising a plurality of con-centric segments of a charged-particle sensitive material configured to detect charged particles emitting from a sample after interaction of the primary charged-particle beam with the sample, wherein each segment of the plurality of concentric segments is configured to collect the emitted charged particles having a range of energy levels and a dominant energy level.

### CROSS-REFERENCE TO RELATED APPLICATIONS

This application claims priority of U.S. application 63/429,684 which was filed on Dec. 2, 2022 and which is incorporated herein in its entirety by reference.

### FIELD

The description herein relates to charged-particle detectors and detection methods, and more particularly, to detectors and detection methods that may be applicable to backscattered charged-particles.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided as dedicated tools for this purpose.

With continuing miniaturization of semiconductor devices, performance demands for inspection systems, including detectors, may continue to increase. For example, electron beam (E-beam) systems with high landing energy (LE) capabilities, e.g., 30 keV and beyond, have attracted great interest as a result of the increasing aspect ratio of vertical structures that may be used in memory devices, as well as continuously shrinking design rules that may require more stringent overlay performance in DRAM and logic devices. High LE systems show great potential in applications such as trench/hole bottom inspection, buried defect/void detection, and overlay/see-through metrology, etc. due to the strong penetration capability of primary electrons (PEs) and the large momentum of backscattered electrons (BSEs) that may allow BSEs to escape the sample material and reach the detector. However, the large amount of energy of PEs in such systems may lead to a much larger interaction volume in the sample and may cause degraded imaging quality.

### SUMMARY

Embodiments of the present disclosure provide systems and methods for defect detection and metrology based on charged particle beams. One aspect of the disclosure is directed to a charged-particle detector for use in a charged-particle beam apparatus. The charged-particle detector may include a plurality of concentric segments of a charged-particle sensitive material configured to detect charged particles emitting from a sample, wherein each segment of the plurality of concentric segments is configured to detect the emitted charged particles having a range of energy levels and a corresponding dominant energy level.

Another aspect of this disclosure is directed to a charged-particle beam apparatus. The charged-particle beam apparatus may include a charged-particle source configured to generate primary charged particles, the primary charged particles forming a primary charged-particle beam along a primary optical axis, and a charged-particle detector comprising a plurality of concentric segments of a charged-particle sensitive material configured to detect charged particles emitting from a sample after interaction of the primary charged-particle beam with the sample, wherein each segment of the plurality of concentric segments is configured to collect the emitted charged particles having a range of energy levels and a dominant energy level.

Another aspect of this disclosure is directed to a charged-particle beam apparatus. The charged-particle beam apparatus may include a compound objective lens comprising a magnetic lens and an electrostatic lens, configured to focus a primary charged-particle beam on a surface of a sample, and a charged-particle detector comprising a plurality of concentric segments of a charged-particle sensitive material configured to detect charged particles emitting from the sample upon interaction of the primary charged-particle beam with the sample, wherein each segment of the plurality of concentric segments is configured to collect the emitted charged particles having a range of energy levels and a dominant energy level.

Another aspect of this disclosure is directed to a charged-particle beam apparatus. The charged-particle beam apparatus may include a charged-particle source configured to generate primary charged particles, the primary charged particles forming a primary charged-particle beam along a primary optical axis to be incident on a sample, a control electrode located immediately upstream from the sample and configured to influence an electrostatic field adjacent to the sample based on an applied voltage signal; and a charged-particle detector comprising a plurality of concentric segments of a charged-particle sensitive material configured to detect charged particles emitting from the sample upon interaction of a primary charged-particle beam with the sample, wherein each segment of the plurality of concentric segments is configured to collect the emitted charged particles having a range of energy levels and a dominant energy level.

Another aspect of this disclosure is directed to a charged-particle beam apparatus. The charged-particle beam apparatus may include a charged-particle source configured to generate primary charged particles, the primary charged particles forming a primary charged-particle beam along a primary optical axis, a charged-particle detector comprising a plurality of segments concentric with the primary charged-particle beam and configured to detect charged particles emitted from the sample; and a controller including circuitry configured to irradiate a region of the sample comprising a feature, with the primary charged-particle beam; generate a plurality of images of the irradiated region, wherein each image of the plurality of images is generated from the charged particles detected by a corresponding segment of the charged-particle detector; determine a characteristic of the feature based on the plurality of images, wherein segmentation of the charged-particle detector allows discrimination of the emitted charged particles by a corresponding dominant energy level and by a corresponding range of energy levels for each segment.

Another aspect of this disclosure is directed to a method of imaging a sample using a charged-particle beam apparatus. The method may include irradiating a region of the sample with a primary charged-particle beam, the region comprising a feature; detecting, using each segment of a plurality of concentric segments of a charged-particle detector, charged particles emitted from the region of the sample; generating a plurality of images of the feature, wherein each image of the plurality of images is generated from the charged particles detected by a corresponding segment of the plurality of concentric segments of the charged-particle detector; and determining a characteristic of the feature based on the plurality of images, wherein each segment of the plurality of concentric segments is configured to detect the emitted charged particles having a range of energy levels and a dominant energy level.

Another aspect of this disclosure is directed to a method of imaging a sample using a charged-particle beam apparatus. The method may include irradiating a region of the sample with a primary charged-particle beam, the region comprising a feature; detecting charged particles emitted from the region of the sample using each segment of a plurality of concentric segments of a charged-particle detector, wherein each segment of the plurality of concentric segments is configured to detect the emitted charged particles having a range of energy levels and a dominant energy level; generating an image of a portion of the feature from the charged particles collected by a segment of the plurality of concentric segments.

Another aspect of this disclosure is directed to a non-transitory computer readable medium storing a set of instructions that is executable by one or more processors of a charged-particle beam apparatus to cause the charged-particle beam apparatus to perform a method. The method may include activating a charged-particle source to generate primary charged particles, the primary charged particles forming a primary charged-particle beam along a primary optical axis; irradiating a region of the sample comprising a feature, with the primary charged-particle beam; detecting charged particles emitted from the sample using a charged-particle detector comprising a plurality of segments concentric with the primary charged-particle beam; generating a plurality of images of the irradiated region, wherein each image of the plurality of images is generated from the charged particles detected by a corresponding segment of the charged-particle detector; and determining a characteristic of the feature based on the plurality of images, wherein segmentation of the charged-particle detector allows discrimination of the emitted charged particles by a corresponding dominant energy level and by a corresponding range of energy levels for each segment.

Another aspect of this disclosure is directed to a non-transitory computer readable medium storing a set of instructions that is executable by one or more processors of a charged-particle beam apparatus to cause the charged-particle beam apparatus to perform a method. The method may include activating a charged-particle source to generate primary charged particles, the primary charged particles forming a primary charged-particle beam along a primary optical axis; irradiating a region of the sample comprising a feature, with the primary charged-particle beam; detecting charged particles emitted from the region of the sample using each segment of a plurality of concentric segments of a charged-particle detector, wherein each segment of the plurality of concentric segments is configured to detect the emitted charged particles having a range of energy levels and a dominant energy level; and generating an image of a portion of the feature from the charged particles collected by a segment of the plurality of concentric segments.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 is a schematic diagram of an exemplary charged-particle beam apparatus comprising a charged-particle detector, consistent with embodiments of the present disclosure.

FIG. 4A is a schematic diagram of an exemplary charged-particle beam apparatus comprising a segmented backscattered electron (BSE) detector, consistent with embodiments of the present disclosure.

FIG. 4B is a top-view of an exemplary segmented BSE detector of FIG. 4A, consistent with embodiments of the present disclosure.

FIG. 5A illustrates simulation results of spatial distribution and energy distribution of backscattered electrons detected on an exemplary segmented BSE detector, consistent with embodiments of the disclosure.

FIG. 5B illustrates a graphical representation of peak energy of charged particles detected in each segment of an exemplary segmented BSE detector, consistent with embodiments of the disclosure.

FIG. 6 illustrates simulated trajectories of backscattered electrons emitted at different emission polar angles from a substrate, consistent with embodiments of the disclosure.

FIGS. 7A-7D illustrate comparisons of energy distribution profiles of backscattered electrons detected by exemplary segmented BSE detectors, consistent with embodiments of the disclosure.

FIG. 8 illustrates a graphical representation of collection efficiency of backscattered electrons for multiple segments of an exemplary segmented BSE detector, consistent with embodiments of the disclosure.

FIG. 9 illustrates a spatial distribution of backscattered electrons detected by radially concentric segments of an exemplary segmented BSE detector, consistent with embodiments of the disclosure.

FIG. 10A is a schematic diagram of an exemplary charged-particle beam apparatus comprising a segmented BSE detector and adjustable working distance, consistent with embodiments of the disclosure.

FIG. 10B is a data plot of BSE collection efficiency across segments of an exemplary segmented BSE detector for a range of working distances, consistent with embodiments of the disclosure.

FIG. 11A illustrates simulated paths of backscattered electrons having a fixed emission energy, emitted at different emission polar angles, and emitted from a substrate adjusted at different heights, consistent with embodiments of the disclosure.

FIG. 11B illustrates simulated trajectories of backscattered electrons having a range of emission energy, at a fixed emission polar angle, and emitted from a substrate adjusted at different heights, consistent with embodiments of the disclosure.

FIG. 12 illustrates a graphical representation of collection efficiency, peak energy, and energy width of backscattered electrons collected by segments of an exemplary segmented BSE detector for varying electric field strength on the sample, consistent with embodiments of the disclosure.

FIGS. 13A and 13B illustrate data plots of simulated peak BSE energy and BSE collection efficiency, respectively, of each segment of a segmented BSE detector for varying electric field strength on the sample, consistent with embodiments of the disclosure.

FIGS. 14A and 14B are graphical representations of BSE collection efficiency of segments of an exemplary segmented BSE detector as a function of the objective lens magnetic field, consistent with embodiments of the disclosure.

FIG. 15 illustrates a series of simulated data plots showing the impact of adjusting magnetic field strength of the objective lens on BSE collection efficiency of segments of a segmented BSE detector, consistent with embodiments of the present disclosure.

FIGS. 16A-16C illustrate schematic diagrams of exemplary charged-particle beam apparatuses configured to compensate focus change due to adjustment of objective lens magnetic field strength, consistent with embodiments of the disclosure.

FIG. 17 is a schematic diagram of an exemplary charged-particle beam apparatus including a BSE detector with adjustable z-height, consistent with embodiments of the disclosure.

FIG. 18 illustrates graphical representation of relationship between different BSE energy components and their corresponding collection efficiency (CE) for a range of BSE detector z-height positions, consistent with embodiments of the disclosure.

FIG. 19 is a flowchart illustrating an example method of imaging a sample using a charged-particle beam apparatus, consistent with embodiments of the disclosure.

FIG. 20 is a flowchart illustrating an example method of imaging a sample using a charged-particle beam apparatus, consistent with embodiments of the disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or any imaging system.

Electronic devices are constructed of circuits formed on a piece of silicon called a substrate. The semiconductor material may include, for example, silicon, gallium arsenide, indium phosphide, or silicon germanium, or the like. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these extremely small ICs is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

A SEM image may be made up of pixels that correspond to locations irradiated by a primary electron beam as the beam scans across the surface of a sample in, e.g., a raster pattern. A higher resolution of pixels (e.g., the number of individual pixels that make up the image) typically corresponds to higher image quality. The more pixels there are, the finer the detail in the image. As structures of interest in ICs become smaller and smaller, it may be more important to produce SEM images with higher resolution to accurately observe structures. However, when a primary electron beam with high landing energy (LE) is used, resolution may be negatively affected.

Landing energy of primary electrons may be determined, for example, based on a difference between the source voltage and the sample voltage, among other things. For example, if the source is operated at −10 kV and the sample is applied −5 kV, the landing energy of primary electrons may be 5 keV. Typically, in a SEM, the landing energy may range from 0.2 keV to 50 keV, based on the application, material being studied, tool condition, among other factors. Some of the ways to change landing energy of the primary electrons of a primary electron beam may include adjusting the potential difference between cathode and extractor, adjusting the sample potential, or adjusting both simultaneously, among other techniques.

In some applications, however, it may be desirable to use high landing energy in a SEM system. The electron source of the SEM may generate a primary electron beam with high LE that is projected onto the sample. High energy electrons may be useful for imaging because they can penetrate deeper into the material of the sample and can reveal additional information about the sample. High LE SEM systems may enable or enhance performance of inspections of the bottom of trenches or holes, detection of buried features such as defects or voids, and performing overlay metrology (e.g., analyzing the alignment of stacked structures). However, the higher energy of the electrons in the primary electron beam means that the electrons may interact with a relatively large volume of material of the sample upon impinging the sample (i.e., the “interaction volume”). Although high energy electrons may penetrate deeper, they may also scatter in other random directions before exiting the material of the sample. Because pixels may be used to form a 2-dimensional map, and electrons may disperse in side-to-side directions, such scattering may cause problems in imaging resolution.

As explained above, a SEM image may be formed of pixels. As a primary beam of a SEM scans across a sample, secondary particles, such as secondary electrons (SEs) and backscattered electrons (BSEs) may be detected by a detector, and information gathered therefrom may be used for forming each pixel in the image. However, with higher LE, the interaction volume in the sample may be increased. The increase in interaction volume may encompass lateral regions (e.g., regions to the sides in the 2-dimensional plane that defines the image consisting of pixels). Pixels may be formed based on information from detected electrons, but information from neighboring pixels may overlap. For example, the detected electrons corresponding to one pixel may include information relating to structures that would be more appropriately located in neighboring pixels. Such effects may cause the SEM image to have poor resolution, and the resulting image may be blurry.

The accuracy, reliability, and throughput of inspection of high-density IC chips using SEMs may depend on the image quality of the system, among other things. One of several ways to obtain and maintain high image quality is to maximize the collection efficiency of signal electrons, such as secondary (SE) and backscattered electrons (BSEs). When a primary electron strikes the surface of a sample, it interacts with a volume of the sample based on the landing energy, sample material, spot size, among other things, and generates a plurality of signal electrons. BSEs have higher energies and originate from deeper areas within the interaction volume, and thus provide information associated with composition and distribution of a material. Therefore, maximum detection of backscattered electrons may be desirable to obtain high quality images of underlying defects or metrology of vertical high aspect-ratio features.

In existing metrology or defect detection techniques using SEMs, a three-dimensional image of a feature-of-interest may be formed by performing multiple scans. In such a case, each scan generates an image based on the BSE signal from BSEs of a certain energy and each scan may correspond to a certain depth of the sample from which the BSEs are emitted. As an example, if a high-aspect ratio feature such as a via is to be imaged, multiple scans may be required to image the entire height or depth of the via and each scan may collect BSEs of a different energy corresponding to a different depth of the via and providing information about the portion of the via at or near that depth. This approach has several disadvantages including increased exposure time of the feature to probe beams resulting in higher possibility of beam damage, low inspection throughput, among other issues.

One of several ways to overcome the issues associated with multiple scans of the feature-of-interest may include performing a single scan which collects a substantial portion of the BSEs generated. A single BSE scan may include a range of BSE energies corresponding to the entire depth of the interaction volume of the primary beam with the sample and extracting information about the feature-of-interest at a certain depth may be challenging. Although, in some cases, an energy filter may be employed to permit only a desired range of energy levels of BSEs emitted from a desired sample depth to pass through to the BSE detector. However, in high landing-energy applications for high image contrast for defect inspection and metrology of three-dimensional structures, a bottom BSE detector located between an objective lens and the sample may be desirable to enhance BSE collection efficiency. In such cases, it may be challenging to employ an energy filter because of the physical space limitations between the sample and the objective lens. Therefore, it may be desirable to provide systems and methods of discriminating BSE signals detected by a bottom BSE detector based on the energy levels of the incoming BSEs.

Further, in some applications, an energy discrimination device such as a reflection type energy filter may be introduced in front of an in-lens detector to filter out (by reflecting back) the secondary electrons and allow BSEs to pass through a high-voltage grid electrode or a filtering grid electrode.

The potential of the high-voltage grid electrode may be set very high (e.g., >10 keV) to serve as a potential barrier for the BSE electrons. Although energy filters may be useful in low landing-energy applications where the energy of secondary electrons is comparable with BSEs and BSEs have small polar emission angles, for high landing-energy applications, an energy filter with very high grid electrode voltages may negatively affect the collection efficiency of BSEs, thereby affecting the quality of images. Furthermore, the voltage applied to the grid may need to be adjusted to collect images with different BSE energies, which renders simultaneous collection of multiple images impossible. This approach may negatively impact the inspection throughput, among other challenges.

Some aspects of the present disclosure may address some challenges by providing a segmented charged-particle detector (e.g., a segmented BSE detector) configured to discriminate the incoming charged particles emitted from the sample based on their energy level. The charged-particle detector may comprise a plurality of concentric segments of a charged-particle sensitive material. The concentric segments of the charged-particle detector may be separated by a charged-particle non-sensitive material. Each concentric segment may be configured to collect BSEs with a corresponding range of energy levels and a dominant energy level within the range of energy levels of BSEs detected by the segment. The dominant energy level of the detected BSE may correspond to BSEs emitted from a certain depth of the sample, thereby providing information associated with a feature-of-interest at a certain depth. BSE signals detected by each concentric segment may be used to generate images simultaneously, which can be further used to form a three-dimensional image of the feature, or a high contrast image of a certain depth of the feature-of-interest may be obtained.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing systems and methods in systems utilizing electron beams (“e-beams”). However, the disclosure is not so limited. Other types of charged particle beams may be similarly applied. Furthermore, systems and methods for wafer inspection or overlay measurement may be used in other imaging systems, such as optical imaging, photon detection, x-ray detection, ion detection, etc.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

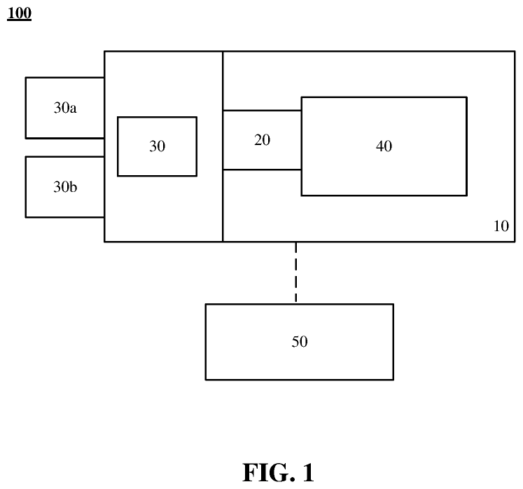

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

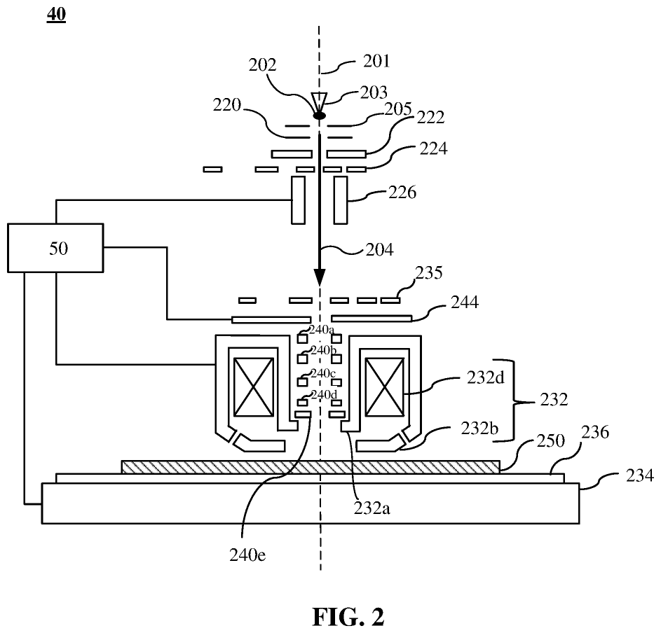

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244.

Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a -e may be different in different embodiments.

Backscattered electrons (BSEs) and secondary electrons (SEs) can be emitted from the part of sample 250 upon receiving primary electron beam 204. A beam separator 240c can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

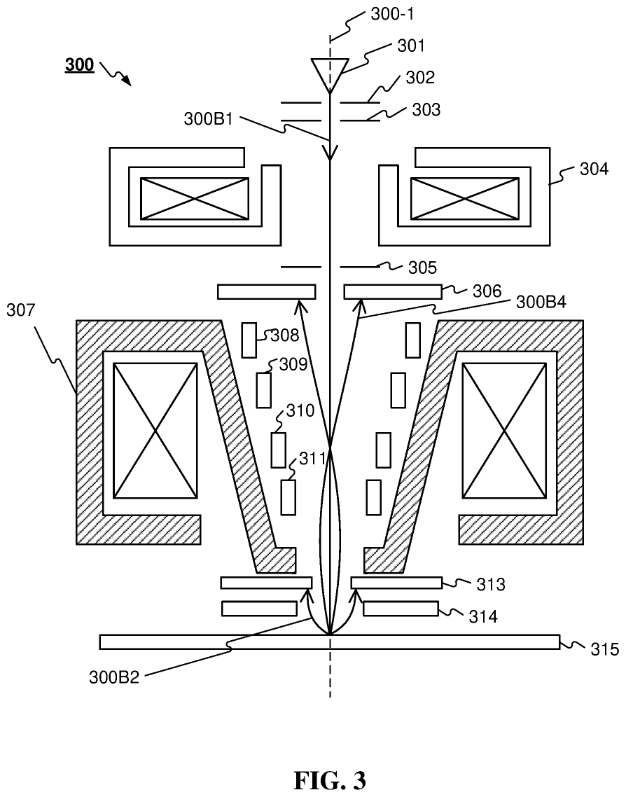

As is commonly known in the art, interaction of charged particles, such as electrons of a primary electron beam with a sample (e.g., sample 315 of FIG. 3, discussed later), may generate signal electrons containing compositional and topographical information about the probed regions of the sample. Secondary electrons (SEs) may be identified as signal electrons with low emission energies, and backscattered electrons (BSEs) may be identified as signal electrons with higher emission energies. Because of their low emission energy, an objective lens assembly may direct the SEs along electron paths and focus the SEs on a detection surface of in-lens electron detector placed inside the SEM column. BSEs traveling along electron paths may be detected by the in-lens electron detector as well. In some cases, BSEs with large emission angles, however, may be detected using additional electron detectors, such as a backscattered electron detector, or remain undetected, resulting in loss of sample information needed to inspect a sample or measure critical dimensions.

Detection and inspection of some defects in semiconductor fabrication processes, such as buried particles during photolithography, metal deposition, dry etching, or wet etching, among other things, may benefit from inspection of surface features as well as compositional analysis of the defect particle. In such scenarios, information obtained from secondary electron detectors and backscattered electron detectors to identify the defect(s), analyze the composition of the defect(s), and adjust process parameters based on the obtained information, among other things, may be desirable for a user.

In other situations, accurate critical dimension measurement of three-dimensional features spanning several microns in depth may be desirable as well. For example, it may be desirable to accurately measure critical dimensions of features, such as vias having a high aspect-ratio with sloped walls, at multiple depths. In such a scenario, the information obtained from secondary electrons, limited to near-surface regions, may be inadequate and misleading. BSEs, having higher emission energy and escaping from deeper into the surface, may provide the desired information about the feature being inspected.

The emission of SEs and BSEs obeys Lambert's law and has a large energy spread. SEs and BSEs are generated upon interaction of primary electron beam with the sample, from different depths of the sample and have different emission energies. For example, secondary electrons originate from the surface and may have an emission energy ≤50 eV, depending on the sample material, or volume of interaction, among other things. SEs are useful in providing information about surface features or surface geometries. BSEs, on the other hand, are generated by predominantly elastic scattering events of the incident electrons of the primary electron beam and typically have higher emission energies in comparison to SEs, in a range from 50 eV to approximately the landing energy of the incident electrons and provide compositional and contrast information of the material being inspected. The number of BSEs generated may depend on factors including, but are not limited to, atomic number of the material in the sample, acceleration voltage of primary electron beam, among other things.

Based on the difference in emission energy, or emission angle, among other things, SEs and BSEs may be separately detected using separate electron detectors, segmented electron detectors, energy band-pass filters, and the like. Examples of implementations of energy band-pass filters based on a relationship between BSE energy and trajectory depth are provided in U.S. Provisional Application No. 63/254,838, which is incorporated herein by reference in its entirety.

Reference is now made to FIG. 3, which illustrates a schematic diagram of an exemplary charged-particle beam apparatus 300 (also referred to as apparatus 300), consistent with embodiments of the present disclosure. Apparatus 300 may comprise a charged-particle source such as, an electron source configured to emit primary electrons from a cathode 301 and extracted using an extractor electrode 302 to form a primary electron beam 300B1 along a primary optical axis 300-1. Apparatus 300 may further comprise an anode 303, a condenser lens 304, a beam-limiting aperture array 305, a signal electron detector 306, a compound objective lens 307, a scanning deflection unit comprising primary electron beam deflectors 308, 309, 310, and 311, and a control electrode 314. In the context of this disclosure, signal electron detectors 306 may be an in-lens electron detector located inside the electron-optical column of a SEM and may be arranged rotationally symmetric around primary optical axis 300-1. In some embodiments, signal electron detector 306 may be referred to as through-the-lens detector, immersion lens detector, upper detector, or a secondary electron detector. It is to be appreciated that relevant components may be added, omitted, or reordered, as appropriate.

An electron source (not shown) may include a thermionic source configured to emit electrons upon being supplied thermal energy to overcome the work function of the source, a field emission source configured to emit electrons upon being exposed to a large electrostatic field, etc. In the case of a field emission source, the electron source may be electrically connected to a controller, such as controller 50 of FIG. 2, configured to apply and adjust a voltage signal based on a desired landing energy, sample analysis, source characteristics, among other things. Extractor electrode 302 may be configured to extract or accelerate electrons emitted from a field emission gun, for example, to form primary electron beam 300B1 that forms a virtual or a real primary beam crossover (not illustrated) along primary optical axis 300-1. Primary electron beam 300B1 may be visualized as being emitted from the primary beam crossover. In some embodiments, controller 50 may be configured to apply and adjust a voltage signal to extractor electrode 302 to extract or accelerate electrons generated from electron source. An amplitude of the voltage signal applied to extractor electrode 302 may be different from the amplitude of the voltage signal applied to cathode 301. In some embodiments, the difference between the amplitudes of the voltage signal applied to extractor electrode 302 and to cathode 301 may be configured to accelerate the electrons downstream along primary optical axis 300-1 while maintaining the stability of the electron source. As used in the context of this disclosure, “downstream” refers to a direction along the path of primary electron beam 300B1 starting from the electron source towards sample 315. With reference to positioning of an element of a charged-particle beam apparatus (e.g., apparatus 300 of FIG. 3), “downstream” may refer to a position of an element located below or after another element, along the path of primary electron beam starting from the electron source, and “immediately downstream” refers to a position of a second element below or after a first element along the path of primary electron beam 300B1 such that there are no other active elements between the first and the second element. For example, as illustrated in FIG. 3, signal electron detector 306 may be positioned immediately downstream of beam-limiting aperture array 305 such that there are no other optical or electron-optical elements placed between beam-limiting aperture array 305 and electron detector 306. As used in the context of this disclosure, “upstream” may refer to a position of an element located above or before another element, along the path of primary electron beam starting from the electron source, and “immediately upstream” refers to a position of a second element above or before a first element along the path of primary electron beam 300B1 such that there are no other active elements between the first and the second element. As used herein, “active element” may refer to any element or component, the presence of which may modify the electromagnetic field between the first and the second element, either by generating an electric field, a magnetic field, or an electromagnetic field.

Apparatus 300 may comprise condenser lens 304 configured to receive a portion of or a substantial portion of primary electron beam 300B1 and to focus primary electron beam 300B1 on beam-limiting aperture array 305. Condenser lens 304 may be substantially similar to condenser lens 226 of FIG. 2 and may perform substantially similar functions. Although shown as a magnetic lens in FIG. 3, condenser lens 304 may be an electrostatic, a magnetic, an electromagnetic, or a compound electromagnetic lens, among others. Condenser lens 304 may be electrically coupled with controller 50, as illustrated in FIG. 2. Controller 50 may apply an electrical excitation signal to condenser lens 304 to adjust the focusing power of condenser lens 304 based on factors including, but are not limited to, operation mode, application, desired analysis, sample material being inspected, among other things.

Apparatus 300 may further comprise beam-limiting aperture array 305 configured to limit beam current of primary electron beam 300B1 passing through one of a plurality of beam-limiting apertures of beam-limiting aperture array 305. Although only one beam-limiting aperture is illustrated in FIG. 3, beam-limiting aperture array 305 may include any number of apertures having uniform or non-uniform aperture size, cross-section, or pitch. In some embodiments, beam-limiting aperture array 305 may be disposed downstream of condenser lens 304 or immediately downstream of condenser lens 304 (as illustrated in FIG. 3) and substantially perpendicular to primary optical axis 300-1. In some embodiments, beam-limiting aperture array 305 may be configured as an electrically conducting structure comprising a plurality of beam-limiting apertures. Beam-limiting aperture array 305 may be electrically connected via a connector (not illustrated) with controller 50, which may be configured to instruct that a voltage be supplied to beam-limiting aperture array 305. The supplied voltage may be a reference voltage such as, for example, ground potential. Controller 50 may also be configured to maintain or adjust the supplied voltage. Controller 50 may be configured to adjust the position of beam-limiting aperture array 305.

Apparatus 300 may comprise signal electron detectors 306 which may be configured to detect substantially all secondary electrons and a portion of backscattered electrons based on the emission energy, emission polar angle, emission azimuthal angle of the backscattered electrons, among other things. In some embodiments, signal electron detectors 306 may be configured to detect secondary electrons, backscattered electrons, or auger electrons. Signal electrons having low emission energy (typically≤50 eV) or small emission polar angles, emitted from sample 315 may comprise secondary electron beam(s) 300B4, and signal electrons having high emission energy (typically>50 eV) and medium emission polar angles may comprise backscattered electron beam(s) 300B3. In some embodiments, 300B4 may comprise secondary electrons, low-energy backscattered electrons, or high-energy backscattered electrons with small emission polar angles. It is appreciated that although not illustrated, a portion of backscattered electrons may be detected by signal electron detector 306. In overlay metrology and inspection applications, signal electron detector 306 may be useful to detect secondary electrons generated from a surface layer and backscattered electrons generated from the underlying deeper layers, such as deep trenches or high aspect-ratio holes.

Apparatus 300 may further include compound objective lens 307 configured to focus primary electron beam 300B1 on a surface of sample 315. Controller 50 may apply an electrical excitation signal to the coils of compound objective lens 307 to adjust the focusing power of compound objective lens 307 based on factors including, but are not limited to, primary beam energy, application need, desired analysis, sample material being inspected, among other things. Compound objective lens 307 may be further configured to focus signal electrons, such as secondary electrons having low emission energies, or backscattered electrons having high emission energies, on a detection surface of a signal electron detector (e.g., in-lens signal electron detector 306). Compound objective lens 307 may be substantially similar to or perform substantially similar functions as objective lens assembly 232 of FIG. 2. In some embodiments, compound objective lens 307 may comprise an electromagnetic lens including a magnetic lens, and an electrostatic lens formed by control electrode 314, polepiece of objective lens, and sample 315.

As used herein, a compound objective lens is an objective lens producing overlapping magnetic and electrostatic fields, both in the vicinity of the sample for focusing the primary electron beam. In this disclosure, though condenser lens 304 may also be a magnetic lens, a reference to a magnetic lens refers to an objective magnetic lens, and a reference to an electrostatic lens refers to an objective electrostatic lens, unless stated otherwise. As illustrated in FIG. 3, objective magnetic lens and objective electrostatic lens, working in unison, for example, to focus primary electron beam 300B1 on sample 315, may form compound objective lens 307. The lens body of magnetic lens and coil may produce the magnetic field, while the electrostatic field may be produced by creating a potential difference, for example, between sample 315, and the polepiece of the objective lens. In some embodiments, control electrode 314 or other electrodes located between polepiece and sample 315, may also be a part of objective electrostatic lens.

Apparatus 300 may further include a scanning deflection unit comprising primary electron beam deflectors 308, 309, 310, and 311, configured to dynamically deflect primary electron beam 300B1 on a surface of sample 315. In some embodiments, scanning deflection unit comprising primary electron beam deflectors 308, 309, 310, and 311 may be referred to as a beam manipulator or a beam manipulator assembly. The dynamic deflection of primary electron beam 300B1 may cause a desired area or a desired region of interest of sample 315 to be scanned, for example in a raster scan pattern, to generate SEs and BSEs for sample inspection. One or more primary electron beam deflectors 308, 309, 310, and 311 may be configured to deflect primary electron beam 300B1 in X-axis or Y-axis, or a combination of X-and Y-axes. As used herein, X-axis and Y-axis form Cartesian coordinates, and primary electron beam 300B1 propagates along Z-axis or primary optical axis 300-1.

Electrons are negatively charged particles and travel through the electron-optical column and may do so at high energy and high speeds. One way to deflect the electrons is to pass them through an electric field or a magnetic field generated, for example, by a pair of plates held at two different potentials, or passing current through deflection coils, among other techniques. Varying the electric field or the magnetic field across a deflector (e.g., primary electron beam deflectors 308, 309, 310, and 311 of FIG. 3) may vary the deflection angle of electrons in primary electron beam 300B1 based on factors including, but are not limited to, electron energy, magnitude of the electric field applied, dimensions of deflectors, among other things.

In some embodiments, sample 315 may be disposed on a plane substantially perpendicular to primary optical axis 300-1. The position of the plane of sample 315 may be adjusted along primary optical axis 300-1 such that a distance between sample 315 and BSE detector 313 may be adjusted. In some embodiments, sample 315 may be electrically connected via a connector (not illustrated) with controller 50 which may be configured to supply a voltage to sample 315 to adjust the position as desired. Controller 50 may also be configured to maintain or adjust the supplied voltage.

In currently existing SEMs, signals generated by detection of secondary electrons and backscattered electrons are used in combination for imaging surfaces, detecting and analyzing defects, obtaining topographical information, accurately measuring critical dimensions of high aspect ratio features, among other things. By detecting the secondary electrons and backscattered electrons, the top few layers and the layers underneath may be imaged simultaneously, thus potentially capturing underlying defects, such as buried particles, measuring critical dimensions, detecting overlay errors, among other things. However, overall image quality may be affected by the efficiency of detection of secondary electrons as well as backscattered electrons. While high-efficiency secondary electron detection may provide high-quality images of the surface, the overall image quality may be inadequate because of inferior backscattered electron detection efficiency. Therefore, it may be beneficial to improve backscattered electron detection efficiency to obtain high-quality imaging, while maintaining high throughput.

One of several ways to enhance image quality and signal-to-noise ratio may include detecting more backscattered electrons emitted from the sample. The angular distribution of emission of backscattered electrons may be represented by a cosine dependence of the emission polar angle (cos(⊖), where ⊖ is the emission polar angle between the backscattered electron beam and the primary optical axis). While a signal electron detector may efficiently detect backscattered electrons of medium emission polar angles, the large emission polar angle backscattered electrons may remain undetected or inadequately detected to contribute towards the overall imaging quality. Therefore, it may be desirable to add another signal electron detector, such as backscattered electron (BSE) detector 313, to capture large angle backscattered electrons.

In some embodiments, signal electron detector 313 may comprise a signal electron detector located between signal electron detector 306 and control electrode 314. In some embodiments, signal electron detector 413 may be located immediately downstream and outside of polepiece of the objective lens, as shown in FIG. 3. In a configuration where signal electron detector 313 is outside the polepiece, it may be desirable to place signal electron detector 313 closer towards compound objective lens 307 or farther from control electrode 314, but aligned with primary optical axis 300-1 to minimize the electrical damage to signal electron detector 313 caused by arcing, for example.

It is appreciated that some existing imaging techniques for defect detection or metrology capture multiple images simultaneously from BSE signals collected using segmented detectors such as FEI's Directional BSE Detector (DBS), as disclosed in publication “Information from Every Angle—Directional BSE Detector for Next-Level Imaging,” FEI Technologies, Inc. The DBS includes a concentric ring design to separate BSEs based on emittance angle (e.g., polar emission angles) while four separate rings allow for simultaneous detection of multiple BSE signals and forming four images simultaneously by utilizing all four rings of the DBS. Further, the publication discloses that BSEs with larger emittance angles may be collected by rings located farther from the optical axis and BSEs with smaller emittance angles may be collected by rings located closest to the primary optical axis. While the FEI's publication discloses discriminating the incoming BSEs based on emittance angle, it does not contemplate that the rings are configured to discriminate the incoming BSEs based on their energy level. Furthermore, it would not be obvious for a person of ordinary skill in the art to modify FEI's DBS to perform energy discrimination using the DBS design of the charged-particle detector because the publication does not discuss or suggest configuring each of the segments to resolve the energy levels of incoming BSE signals. As a contrast, the disclosed embodiments in the present disclosure provide segmented BSE detectors for high-landing energy applications. Each segment of the segmented BSE detector may be configured to detect the signal based on a dominant energy level or the range of energy level of the incoming BSE. Configuring may include adjusting a width of the segments, for example. Other techniques of configuring each segment may include adjusting a z-axis position of the sample, adjusting a z-position of the detector, adjusting a magnetic field strength of the objective lens, adjusting an extraction potential, adjusting an electrostatic field adjacent to the sample, among other things, each of which is discussed in detail in this disclosure.

For high landing energy applications, a bottom BSE detector located between a sample and a polepiece of an objective lens may be employed to collect BSEs with medium to large emission angles in the range of 15°-65°. Details of systems and methods using a bottom BSE detector to improve collection efficiency are discussed in U.S. Pat. Publication No. 2021/0319977 A1, which is incorporated herein by reference in its entirety. As described previously, investigations have revealed a strong correlation between trajectory depth and emission energy of BSEs. In other words, BSE signals with higher or lower energy can be found to be coming from a relatively shallower or deeper location inside a sample's material, respectively. While in some cases an energy filtering device may be used to selectively allow electrons of desired energy levels to pass through to a detector, physical space limitations in apparatuses using a bottom BSE detector may not allow so. Accordingly, it may be desirable to provide a bottom BSE detector to detect BSEs with an energy discrimination capability while maintaining high BSE collection efficiency and high inspection throughput.

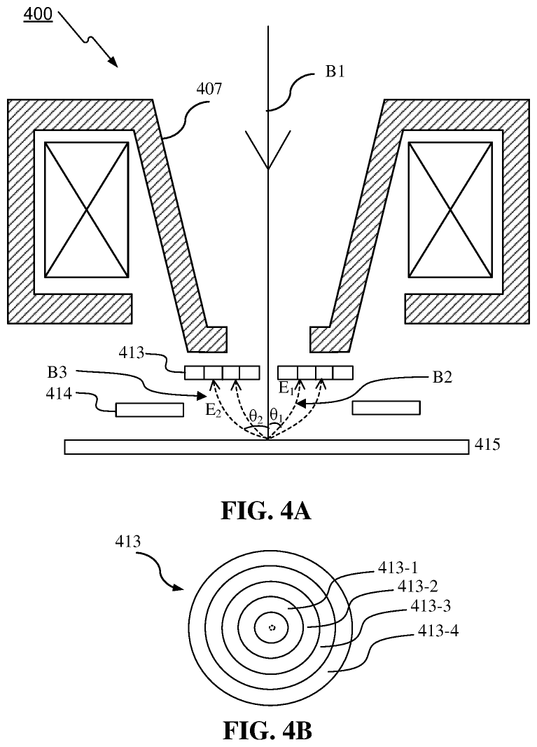

Reference is now made to FIGS. 4A, which illustrates a schematic diagram of a portion of an exemplary charged-particle beam apparatus 400 comprising a segmented backscattered electron (BSE) detector 413. Apparatus 400 may include an objective lens 407 substantially similar to and performing substantially similar functions as compound objective lens 307 of apparatus 300. Primary electron beam B1 may travel through the electron-optical column including objective lens 407, central opening of segmented BSE detector 413, and central opening of control electrode 414 and interact with a region of sample 415. As a result of the interaction of primary electron beam B1 with sample 415, secondary charged particles including secondary electrons, backscattered electrons, auger electrons, X-rays, among other particles, may be emitted from sample 415.

As illustrated in FIG. 4A, BSE beam B2 and BSE beam B3 may comprise electrons having different energy or energy levels E1 and E2, respectively, such that E1<E2. In some embodiments, the polar emission angle θ1 of BSE beam B2 may be smaller than polar emission angle θ2 of BSE beam B3. In some embodiments, although not illustrated, polar emission angle of BSE beams B2 and B3 may be substantially similar while the energy levels E1 and E2 may be different. Substantially similar polar emission angle, as used herein, refers to the similarity in emission angles such that the variations in the emission angles of electrons or beams comprising the electrons emitting from the sample are negligible and within acceptable limits.

In some embodiments, BSE detector 413 may be a bottom BSE detector located between sample 415 and a polepiece of objective lens 407. In some embodiments, BSE detector 413 may be located between control electrode 414 and a polepiece of objective lens 407. BSE detector 413 may be placed such that it is substantially perpendicular to a primary optical axis along which primary electron beam B1 travels through the electron-optical column of apparatus 400. The term “substantially perpendicular,” as used herein, refers to the perpendicularity of an element with respect to an axis or another element, such that there is a negligible offset or deviation, typically less than 0.1° or within an acceptable range, from an angle of 90° therebetween. In some embodiments, BSE detector 413 may be placed such that it is substantially perpendicular to a primary optical axis and such that its central opening is aligned with the primary optical axis, as illustrated in FIG. 4A. It is to be appreciated that while the dimensions, spacings, and the sizes of elements of apparatus 400 are not illustrated to scale, their relative positions and locations are representative.

In some embodiments, BSE detector 413 may be a segmented BSE detector comprising a plurality of radially concentric segments 413-1, 413-2, 413-3, 413-4, of charged-particle sensitive material separated by a non-sensitive material or substrate. A top-view of an exemplary segmented BSE detector comprising four concentric segments is illustrated in FIG. 4B, consistent with some embodiments of the present disclosure. The charged-particle sensitive material may be sensitive to charged particles, such as ionizing radiation, electrons, X-rays, or photons, among other charged particles such that it may be configured to detect an incident charged particle and generate a corresponding signal in response to the detection. The non-sensitive material separating the concentric segments may comprise the substrate material of BSE detector 413 or any material having low detection sensitivity for charged particles. BSE detector 413 may be placed in the apparatus 400 such that its central opening is aligned with the primary optical axis of apparatus 400. In some embodiments, each segment of BSE detector 413 may be configured to detect BSEs of different energy levels or BSEs of different ranges of energy levels. For example, segment 413-1 may be configured to detect BSEs having an emission energy in the range 2-5 keV, segment 413-2 may be configured to detect BSEs having an emission energy in the range 5-10 keV, segment 413-3 may be configured to detect BSEs having an emission energy in the range 10-20 keV, and segment 413-4 may be configured to detect BSEs having an emission energy in the range 20-50 keV. It is to be appreciated that the number of segments and the energy ranges detected by each segment are non-limiting examples, and BSE detectors may comprise fewer or more segments, and energy thresholds for each segment may be adjusted, as discussed in later sections of this disclosure. It is to be further appreciated that the width of each segment may be uniform or non-uniform.

In some embodiments, BSE detection signals may be used to reconstruct images of sample structures under inspection or observation. The images may be two-dimensional images, or three-dimensional images generated from multiple two-dimensional images. In some embodiments, a three-dimensional image may be formed from images generated by signals detected in each segment of BSE detector 413. Additionally, or alternatively, a three-dimensional image may be formed from multiple images generated from signals detected by a single segment. Signals detected by a single segment may represent BSEs having an energy range, thereby emitted from a certain depth or a certain depth range. It may be desirable to generate a three-dimensional image from multiple images based on signals detected by a single segment to collect information about a feature at a particular depth, such as critical dimension at a height. In other cases, it may be desirable to generate a three-dimensional image from multiple images based on signals detected by multiple segments simultaneously.

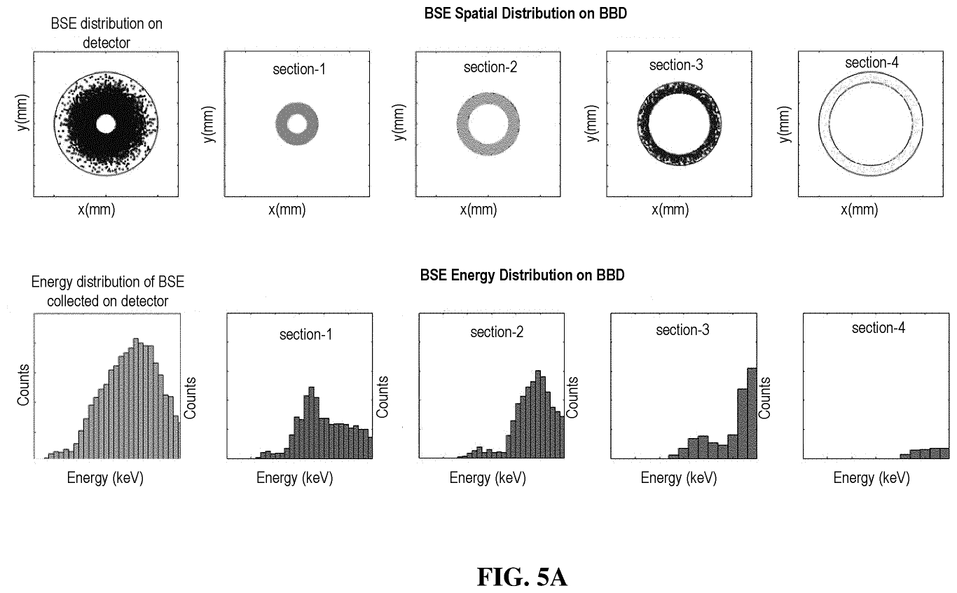

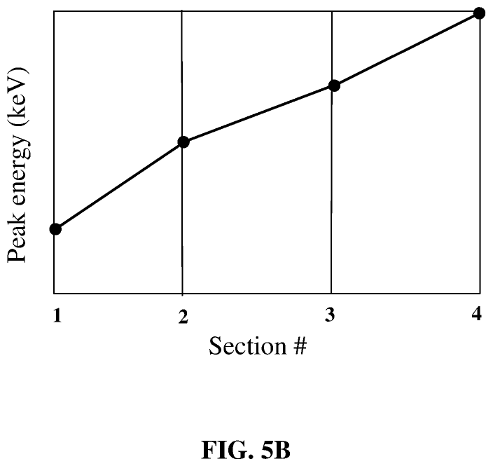

Reference is now made to FIG. 5A, which illustrates simulation results of spatial distribution and energy distribution of backscattered electrons detected on an exemplary segmented BSE detector such as BSE detector 413, consistent with embodiments of the disclosure. In some embodiments, BSE detector 413 may be referred to as a bottom BSE detector (BBD). In the example shown in FIG. 5A, BSE detector 413 is a BBD with four segments. It is to be appreciated that “segments” of a segmented BSE detector may also be interchangeably referred to herein as “sections.” Accordingly, a segmented BSE detector, such as BSE detector 413, may include multiple sections, as referred to in FIG. 5A. The simulated results include a spatial distribution of BSEs, as shown in the images on the top row of FIG. 5A. The images on the top row show a spatial distribution of BSEs on a BBD (e.g., BSE detector 413 of FIG. 4B) and a spatial distribution of BSEs on individual segments or sections of the BBD.

In some embodiments, section 1 may correspond to segment 413-1 of BSE detector 413 of FIG. 4B. Section 1 may be the segment closest to the central opening of the BSE detector and may be configured to detect low energy BSE signals, representing the BSEs emitted from a deeper region of the sample, thereby providing information associated with and about features present in that region. Sections 2, 3, and 4 may correspond to segments 413-2, 413-3, and 413-4 of BSE detector 413 of FIG. 4B.

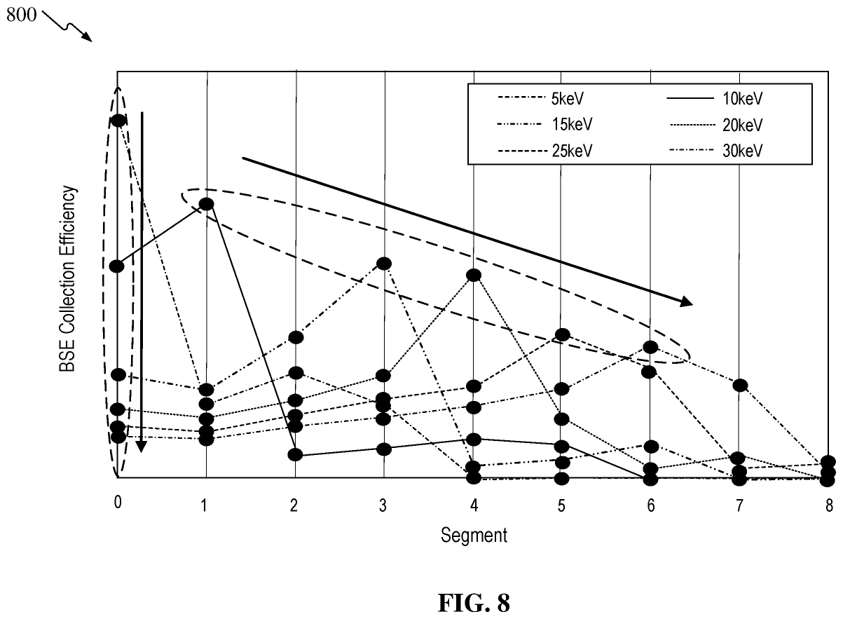

The images shown in bottom row of FIG. 5A illustrate simulated results of energy distribution of BSEs collected on BBD and an energy distribution of BSEs on individual segments of the BBD. The energy distribution plots shown in the bottom row for each segment show a wide distribution of emission energy collected by the corresponding segment. The energy distribution plots further show a predominant energy level, or a peak energy of detected BSEs associated with each segment. As shown in FIG. 5B, which illustrates a relationship between the peak energy of detected BSEs associated with each segment of a segmented BSE detector (e.g., BSE detector 413 of FIG. 4B), the peak energy of detected BSEs collected by each segment increases as the radial distance from the center of the opening of BSE detector increases. In other words, a BSE detector (e.g., BSE detector 413 of FIG. 4B) may be segmented based on the peak energy of the detected BSEs. The relationship between BSE collection efficiency, BSE emission energy, and segments of a BSE detector is discussed in detail with reference to FIG. 8.

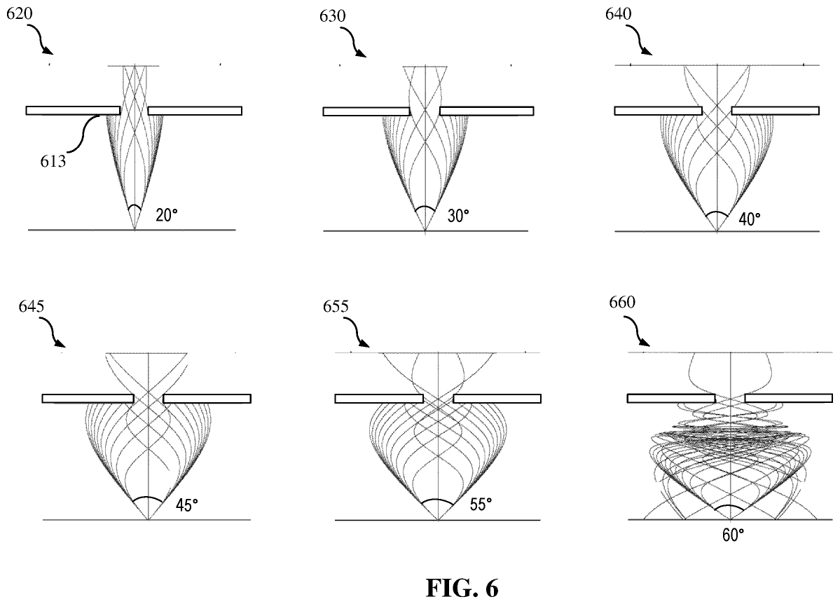

FIG. 6 illustrates simulated trajectories of BSEs emitted at different emission polar angles from a substrate, consistent with embodiments of the disclosure. Data capture plot 620 shows a simulated trajectory of BSEs having a range of emission energy emitted at a polar emission angle of 20°. In some embodiments, the emission energy of BSEs may be in the range of 1 keV to 50 keV, 2 keV to 50 keV, 3 keV to 50 keV, 4 keV to 50 keV, 5 keV to 50 keV, 10 keV to 50 keV, 15 keV to 50 keV, or any appropriate range of BSE emission energy. In some embodiments, the BSE emission energy may be in the range of 1 keV to the landing energy of primary electron beam. BSE detector 613 is configured to detect BSEs emitted from the substrate. While all BSEs shown in data capture plot 620 are emitted at a polar emission angle of 20°, a portion of the BSEs with low emission energy may be collected in a region of BSE detector 613 radially closer to the primary optical axis and BSEs with higher emission energy may be collected in a region of BSE detector 613 radially farther from the primary optical axis. In other words, a portion of the BSEs with low emission energy may be incident on the detection surface of BSE detector 613 at a smaller off-axis distance and the BSEs with higher emission energy may be incident on the detection surface of BSE detector 613 at a larger off-axis distance. In the context of this disclosure, off-axis distance refers to the horizontal distance from the primary optical axis.

In some embodiments, the magnetic field generated by the objective lens (e.g., objective lens 407 of FIG. 4A) may influence the path of the BSEs emitted from the surface based on the energy of the BSEs. The low energy BSEs may be influenced more than the higher energy BSEs. In this context, influencing the path of the BSEs by the magnetic field of the objective lens refers to changing the trajectory of the BSEs such that they are deflected towards the primary optical axis. In some cases, the deflection of the trajectory of low energy BSEs may cause the BSEs to escape through the central opening of BSE detector 613 without being detected, resulting in loss of collection efficiency. One of several ways to capture the low energy low emission angle BSEs may include reducing the cross-section of the central opening of BSE detector 613. However, in some situations, it may hinder the path of primary electron beam directed towards the sample, among other challenges. As illustrated in data capture plot 620 of FIG. 6, the radial separation between BSEs of different emission energy on the detection surface of BSE detector 613 emitted with a polar emission angle of 20° is low.

Data capture plots 630 and 640 show simulated trajectory of BSEs having a range of emission energy emitted at a polar emission angle of 30° and 40°, respectively. In comparison with data capture plot 620, the radial separation or radial resolution of the BSEs of different emission energy on the detection surface of BSE detector 613 emitted with a higher emission angle increases, as shown in data capture plots 630 and 640.

Data capture plot 645 illustrates the simulated trajectory of BSEs having a range of emission energy emitted at a polar emission angle of 45°. As shown, the radial separation between the BSEs of different emission energy may be higher than the radial separation or radial resolution for BSEs having a polar emission angle of 40°. In addition, the emission yield of BSEs is high at a polar emission angle of 45°. Therefore, it may be desirable to use a radially segmented BSE detector, such as BSE detector 413 of FIG. 4B, to maximize the detection of BSEs emitted at a polar emission angle of 45°, for example, based on the emission energy of the BSE incident on BSE detector.

In data capture plots 655 and 660, which show the simulated trajectory of BSEs having a range of emission energy emitted at a polar emission angle of 55° and 60°, respectively, though the polar emission angle is higher, the radial separation, and therefore the detectability based on emission energy may not be high. This may be attributed to the larger deflection of high emission angle BSEs, causing BSEs to be absorbed or reflected back towards the substrate, thereby reducing the number of BSEs collected by BSE detector 613.

As previously discussed, radially segmented BSE detectors, such as BSE detector 413 of FIG. 4B, may be used to discriminate the incoming BSEs based on their emission energy. Further, each segment (e.g., segments 413-1-413-4 of FIG. 4B) may be configured to detect BSEs having a BSE emission energy in a particular range of energy level and each segment may have an associated predominant energy level or a peak energy. Because each segment has an associated peak energy within the distribution of detected BSE emission energy, a larger number of spatially arranged segments may result in a higher energy-filtering resolution. In other words, the resolution of a segmented BSE detector may be improved by increasing the number of segments based on the predominant energy level of the BSEs it is configured to detects.

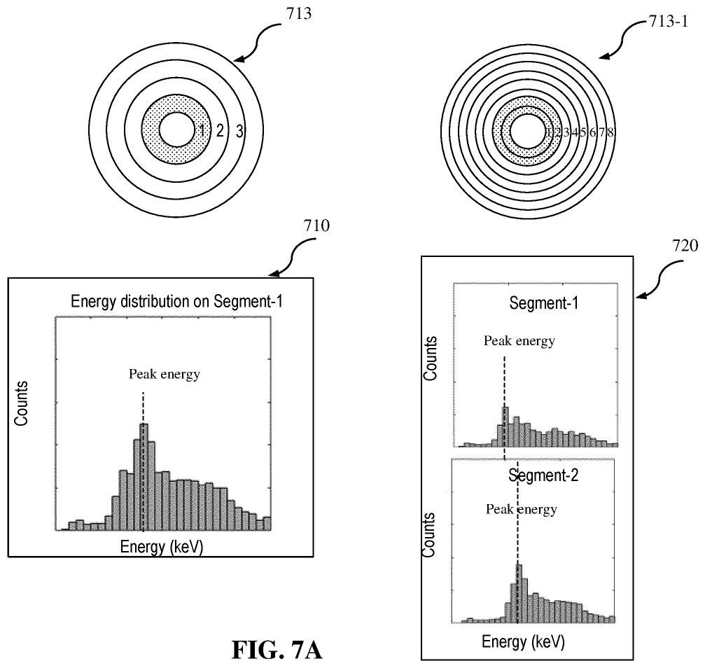

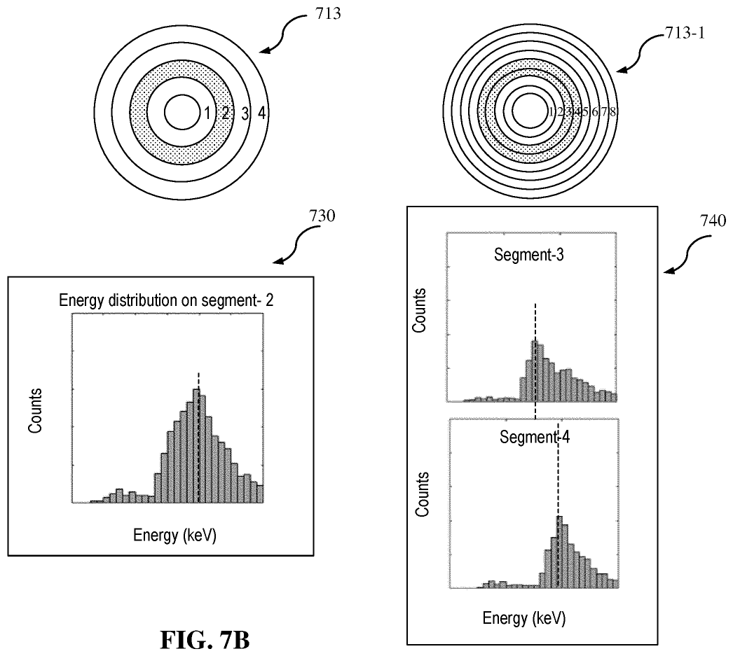

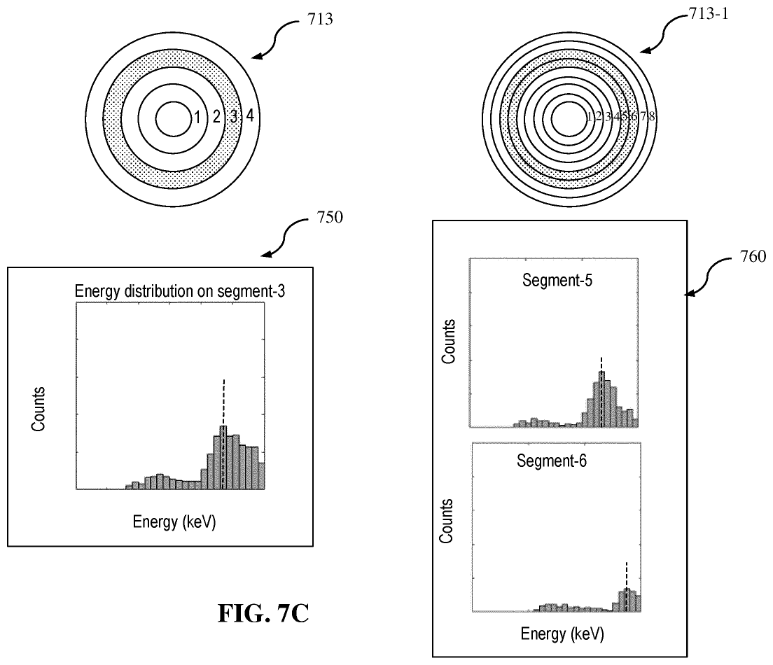

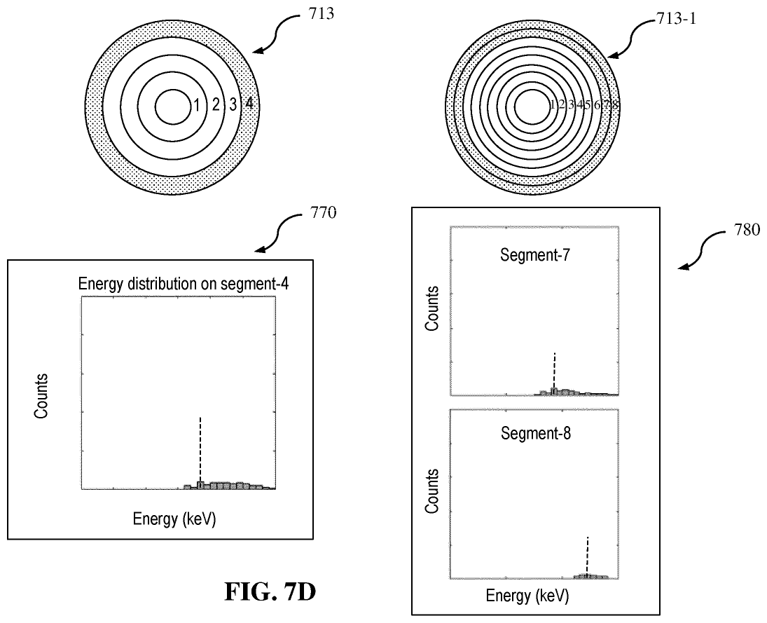

Reference is now made to FIGS. 7A-7D, which illustrate energy distribution profiles of backscattered electrons detected by exemplary segmented BSE detectors, consistent with embodiments of the disclosure. FIG. 7A illustrates a schematic of top view of a BSE detector 713 having four segments (e.g., segments 1, 2, 3, and 4) with an activated segment-1. Data plot 710 illustrates the spatial energy distribution profile of segment-1, which upon activation is configured to detect the incoming BSEs. In this context, activating a segment of a BSE detector may include enabling the collection or detection of BSEs incident on the detector surface associated with the segment. The segment of a segmented BSE detector may comprise material sensitive to charged particles including, but not limited to, ionizing radiation, electrons, X-rays, among other particles.

In some embodiments, a controller (e.g., controller 50 of FIG. 2) may be configured to apply an electrical signal, such as a voltage or a current signal, to activate one or more segments, sequentially or in parallel. For example, controller 50 may activate segment-1 to collect BSEs coming from deeper regions of the sample, thereby having lower emission energy. In some embodiments, controller 50 may further be configured to generate an image (e.g., a backscattered electron image) based on the BSE signal produced by BSEs collected or detected by segment-1. It is to be appreciated that controller 50 may be configured to generate multiple images, or process multiple images to form a composite image, among other functions. An image processor, controlled by controller 50, may be configured to form the composite image. In this context, a composite image may be formed by stitching together a plurality of images captured by the image acquirer. For example, a composite image may include a three-dimensional image formed by stitching together a plurality of two-dimensional images captured at different depths.

In some embodiments, a BSE detector may be segmented into a m number of segments, where m is a positive integer, and m is ≥2. An exemplary BSE detector 713-1 having eight segments is shown in FIG. 7A. It is to be appreciated that the number of segments, width of each segment, or the material of each segment may be adjusted appropriately, as desired. It is to be further appreciated that one or more segments of BSE detector 713-1 may be activated individually, or simultaneously, or based on a predetermined timing. For example, controller may be configured to activate a segment of the plurality of segments for a predetermined time while the other segments are deactivated. After the predetermined time is elapsed, another segment may be activated for a second predetermined time. In some embodiments, one or more segments may be activated based on a predetermined duty-cycle.

Data plot 720 illustrates the BSE energy distribution profiles and peak energy levels identified for segments 1 and 2 of BSE detector 713-1. In comparison with BSE detector 713, which has a single peak energy or a predominant energy for a given range of BSE emission energy, BSE detector 713-1 may be configured to have two segments (e.g., segments 1 and 2), and therefore two predominant energy levels, which may be used to further resolve the incoming BSEs based on their energy. A higher energy-resolution may allow a user to obtain information or form images from a specific depth, while filtering out the other BSE signals, thereby resulting in more accurate inspection and metrology.

As an example, controller 50 may activate only segment 1 or segment 2 at a time, thus generating an image based on BSE signals having emission energy distribution in a certain range or having a specific peak energy level, which may be correlated with a specific depth of the sample from which the BSE signals may originate.

As illustrated in FIG. 7B, data plot 730 shows the BSE energy distribution profile of segment 2 of segmented BSE detector 713. Segment 2 of BSE detector 713 is indicated as being activated. In comparison, a narrower energy distribution and more distinctly identifiable peak energy levels may be obtained from segments 3 and 4 of BSE detector 713-1. Data plot 740 represents the energy distribution profile of segments 3 and 4 of BSE detector 713-1. Data plots 750 and 760 show the BSE energy distribution profiles of segment 3 of BSE detector 713 and segments 5 and 6 of BSE detector 713-1, respectively, as shown in FIG. 7C. Data plots 770 and 780 show the BSE energy distribution profiles of segment 4 of BSE detector 713 and segments 7 and 8 of BSE detector 713-1, respectively, as shown in FIG. 7D.

FIG. 8 illustrates a graphical representation of simulated collection efficiency of backscattered electrons for multiple segments of an exemplary segmented BSE detector, consistent with embodiments of the disclosure. In FIG. 8, data plot 800 represents the collection efficiency of individual segments of an exemplary segmented BSE detector, for BSEs having an emission energy ranging from 5 keV to 30 keV and a polar emission angle of 45°. It is to be appreciated that range of emission energy used for simulation purposes is exemplary and non-limiting, and other energy ranges may be used as well. The BSE detector may comprise eight segments (e.g., BSE detector 713-1 of FIGS. 7A-7D), identified as segments 1-8. Segment 0 in data plot 800 does not represent an actual detection segment, but instead represents the central opening of a segmented BSE detector. In that regard, the collection efficiency of segment 0 is not the actual collection efficiency because the BSEs are not collected or detected, instead, it may be regarded as the number of BSEs lost or escaping through the central opening of the BSE detector.

As shown in data plot 800, the number of BSEs lost through the central opening of the BSE detector may decrease as the BSE emission energy increases. As an example, approximately 45% of low energy BSEs (e.g., 5 keV or less) and approximately 5% of high energy (e.g., 25 keV or more) may pass through the central opening without being detected by a BSE detector. This may be because the low energy BSEs may be influenced more than the high energy BSEs by the magnetic field of the objective lens, which deflects the BSEs closer to the primary optical axis.

As further illustrated in data plot 800, with respect to the collection efficiency, a distinct predominant or a peak energy component may exist for a segment of the segmented BSE detector. In other words, a segment may detect BSEs having a specific energy more than the other energy components of the BSE signal. For example, segment 1 may have the maximum collection efficiency for BSEs of 10 keV, segment 3 may have the maximum collection efficiency for BSEs of 15 keV, segment 4 may have the maximum collection efficiency for BSEs of 20 keV, segment 5 may have the maximum collection efficiency for BSEs of 25 keV, and segment 6 may have the maximum collection efficiency for BSEs of 30 keV.

As further illustrated in data plot 800, the higher the BSE energy, the peak position of the maximum collection efficiency may be in a segment located at a farther off-axis distance. In other words, segments located farther away from the primary optical axis may be configured to selectively detect BSEs having higher energy, thereby enabling discriminating different energy components of the incoming BSEs by using a segmented BSE detector. This may be because the high kinetic energy BSEs may be less influenced by the magnetic field of the objective lens and may travel a larger distance without being deflected or deviated from their desired trajectory.

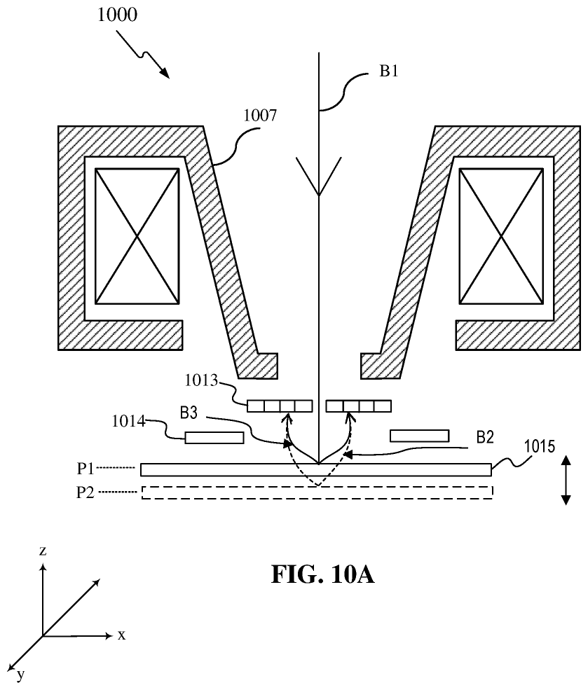

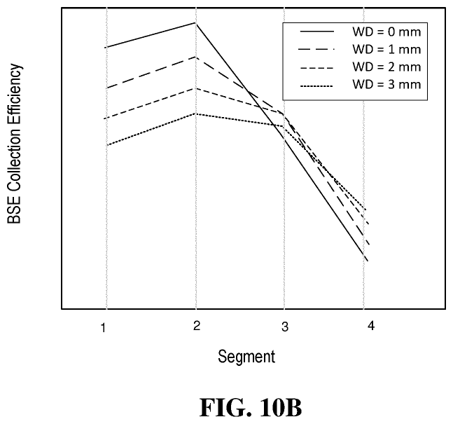

In some embodiments, a BSE detector may be configured such that a segment of the detector detects a distinct range of a predominant energy BSE signal. Configuring the BSE detector (e.g., BSE detector 713-1 of FIGS. 7A-7D) may include adjusting a radial width of a segment, adjusting the electromagnetic field of the objective lens, adjusting a distance between the substrate and the BSE detector (discussed later with reference to FIGS. 10A and 10B), adjusting the height of the BSE detector with respect to the substrate position, adjusting the electric field on the sample, adjusting the extraction voltage between the charged particle source (e.g., electron source) and the substrate, adjusting the magnetic field strength of objective lens, or compensating focus due to the change in magnetic field strength of objective lens. One or more of these factors, such as magnetic field strength of the objective lens, distance between the substrate and the BSE detector, extraction voltage, control electrode voltage, BSE detector height, or a combination thereof, may be adjusted to adjust the spatial distribution of BSE signals on a segmented BSE detector and the optimization of image contrast such that each segment is configured to detect a distinct range of a predominant energy BSE signal, as illustrated in data plot 800, for example.

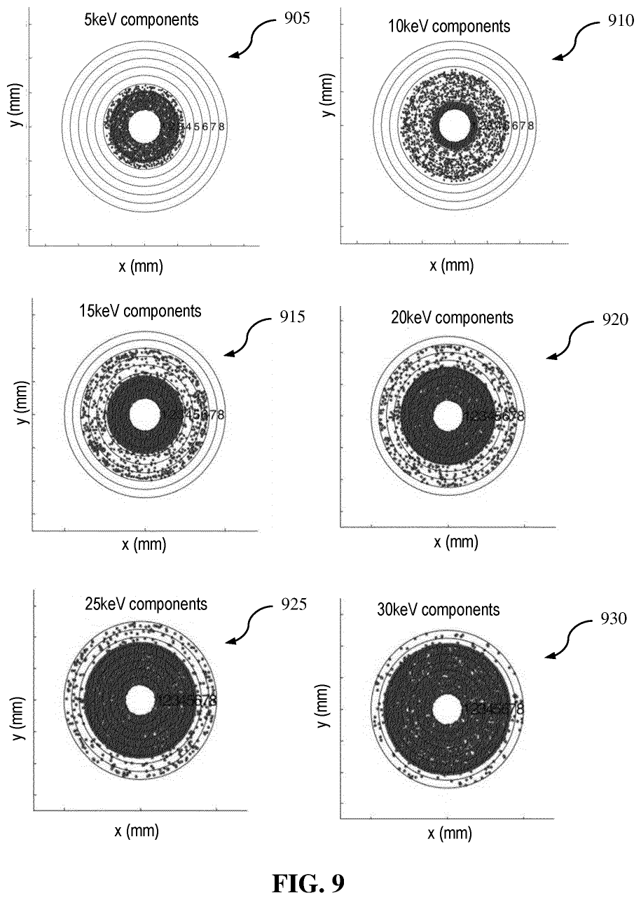

Reference is now made to FIG. 9, which illustrates the spatial distribution of BSEs detected by radially concentric segments of an exemplary segmented BSE detector, consistent with embodiments of the disclosure. In FIG. 9, a plurality of simulated images 905, 910, 915, 920, 925, and 930 represent a detection footprint or a spatial distribution of BSEs of energy 5 keV, 10 keV, 15 keV, 20 keV, 25 keV, and 30 keV, respectively, on a segmented BSE detector (e.g., BSE detector 713-1 of FIGS. 7A-7D). For example, substantially all BSEs having an energy of 10 keV or less may be collected by the segments closest to the primary optical axis, such as segments 1, 2, 3, and 4. As illustrated in simulated image 910, although the distribution of BSEs spans across four segments, the density of distribution of BSE signals is the highest in segment 1, consistent with data plot 800. As another example, substantially all BSEs having an energy of 20 keV or less may be collected by the segments 1-7. As illustrated in simulated image 920, although the distribution of BSEs spans across seven segments, the density of distribution of BSE signals is the highest in segment 4, consistent with data plot 800. Therefore, each segment may have a predominant energy level of BSEs that it may be configured to detect, allowing discriminating and filtering the BSE signals based on their emission energy.

FIG. 10A illustrates a schematic diagram of an exemplary charged-particle beam apparatus 1000 comprising a segmented BSE detector, consistent with embodiments of the disclosure. Objective lens 1007, BSE detector 1013, and control electrode 1014 may be substantially similar and may perform substantially similar functions as objective lens 407, BSE detector 413, control electrode 414, respectively, of apparatus 400.

In comparison with apparatus 400, a position of sample 1015 in the z-axis may be adjustable in apparatus 1000. In some embodiments, z-axis position of sample 1015 may be adjusted to change the distance between a BSE detector 1013 and sample 1015, i.e., the working distance. As illustrated, adjusting the z-axis position of sample 1015 from an initial position P1 to P2 (represented by a rectangle of broken lines) may increase the working distance. BSE beam B3 may be emitted from a surface of sample 1015 at position P1 and BSE beam B2 may be emitted from sample 1015 at position P2. A change in the trajectory of BSE beams B2 and B3 caused by a change in z-axis position of the surface of sample 1015 from which they originate, may result in change in the peak energy of the collected BSEs incident on a segment of BSE detector 1013. For example, while BSE beams B2 and B3 may have different peak energy levels, they may land on the same segment of BSE detector 1013, based on the z-axis position of sample 1015.

In some embodiments, adjusting the z-axis position of sample 1015 may change the BSE energy detection range of BSE detector 1013. For example, increasing the working distance as shown in FIG. 10A, may increase the BSE energy range detectable by BSE detector 1013. In some embodiments, adjusting the z-axis position of sample 1015 may change the BSE collection efficiency. For example, increasing the working distance may cause more BSEs to be deflected by magnetic field of objective lens 1007 closer towards the primary optical axis along which primary electron beam B1 travels, thus allowing more BSEs to escape through the central opening of BSE detector 1013. In some embodiments, adjusting the z-axis position of sample 1015 may change the BSE collection efficiency uniformity across multiple segments of BSE detector 1013, as illustrated in FIG. 10B. For example, increasing the working distance may improve the uniformity of BSE collection efficiency across multiple segments of a segmented BSE detector (e.g., BSE detector 1013).

In some embodiments, although not shown, the peak energy of BSEs collected by a segment of the plurality of segments may vary based on the working distance. This may allow further filtering of incoming BSEs based on their energy. In other words, the working distance may be adjusted to filter BSEs within a particular segment of BSE detector 1013. The ability to adjust the peak energy of the detected BSEs, the energy detection range of BSEs, or the BSE collection efficiency uniformity across multiple segments by adjusting the z-axis position of the sample may provide enhanced sensitivity and accuracy for metrology or defect inspection.

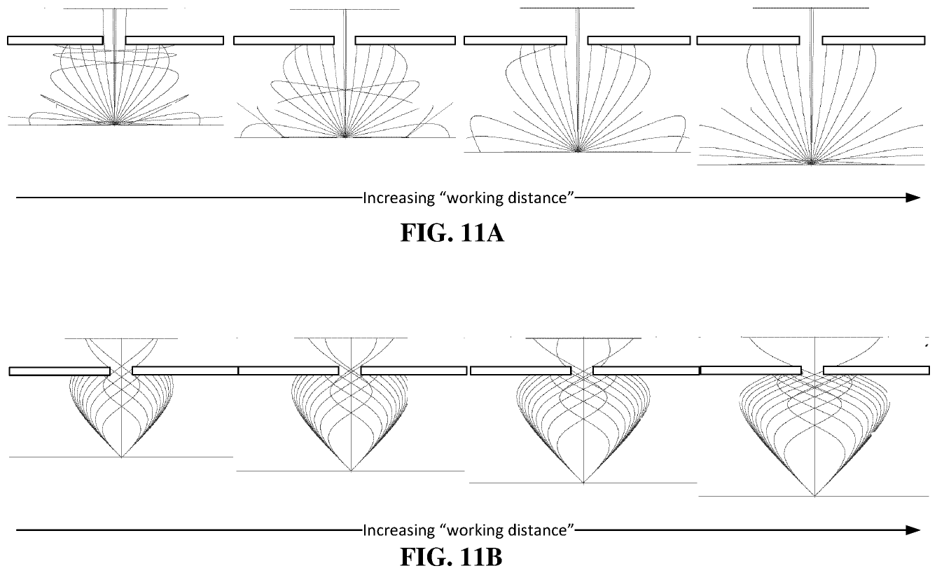

In some embodiments, the z-axis position of the sample may be adjusted based on a landing energy of the charged particles forming the primary charged-particle beam B1. It is desirable to adjust the z-axis position of the sample based on the landing energy of the primary charged-particle beam B1 to allow better discrimination of BSE energy between multiple segments of BSE detector 1013. Reference is now made to FIGS. 11A and 11B, which illustrate simulated trajectories of BSEs

at varying emission angles and at a fixed polar emission angle, respectively, consistent with embodiments of the disclosure. FIG. 11A illustrates simulated trajectories of BSEs having a fixed emission energy (e.g., 30 keV) at various polar emission angles and various working distances.

In some embodiments, BSEs having a smaller polar emission angle may be detected by segments closer to the primary optical axis or may escape through the central opening of a BSE detector without being detected. BSEs having a larger polar emission angle may either land on the segments at a larger off-axis distance or be blocked by other components such as control electrode (e.g., control electrode 1014 of FIG. 10A) or may be reflected back to the substrate. As the working distance increases, the magnetic field generated by an objective lens (e.g., objective lens 1007 of FIG. 10A) gets weaker and the BSEs may be less influenced, making it easier for BSEs to travel substantially undeflected or without deviations. This may allow the BSEs with the same energy component land on a different segment when the working distance is different. In other words, a certain radial segment may collect or detect BSEs having a different emission energy, when the working distance is different.

As previously described, the BSE emission yield may be maximum at a polar emission angle of 45°. FIG. 11B illustrates simulated trajectories of BSEs of different energy components emitted at a fixed polar emission angle of 45° and when the working distance is varied. As the working distance increases, the BSEs may travel further away from the primary optical axis before being collected by the BSE detector, thereby experiencing a larger focusing force from objective lens (e.g., objective lens 1007 of FIG. 10A) to deflect the BSEs back towards the primary optical axis. In some embodiments, though not illustrated, adjusting the working distance may change the peak BSE energy detected by a segment of a BSE detector (e.g., BSE detector 1013 of FIG. 10A).

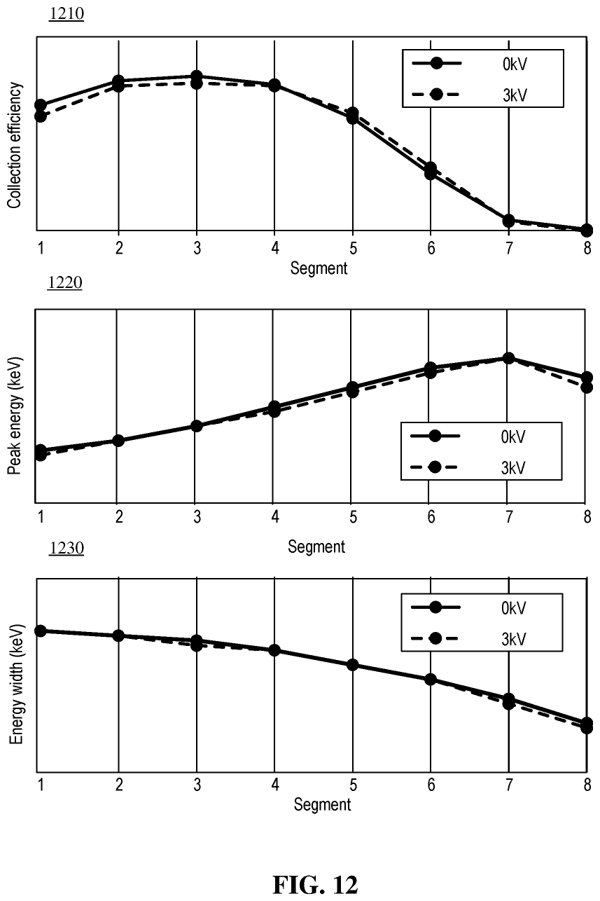

In some embodiments, the BSE spatial distribution, BSE collection efficiency, or detected peak BSE energy on one or more segments of a segmented BSE detector (e.g., BSE detector 713-1 of FIGS. 7A-7D) may be adjusted by adjusting the electric field strength at the surface of the sample (e.g., sample 415 of FIG. 4). Adjusting the electric field strength at the sample surface may include, but is not limited to, adjusting a voltage of control electrode (e.g., control electrode 414 of FIG. 4) close to the sample, or adjusting the potential difference between the sample and a polepiece of the objective lens (e.g., objective lens 407 of FIG. 4A). In some embodiments, controller 50 may be configured to apply or adjust the voltage applied to the control electrode such that the adjustment of the applied voltage adjusts one or more of the BSE collection efficiency, peak BSE energy, or BSE energy width. FIG. 12 illustrates graphical representations of simulated data showing the effect of adjusting

the electric field strength on change in the collection efficiency, peak energy, and energy width of BSEs collected by different segments of an exemplary segmented BSE detector, consistent with embodiments of the disclosure. In some embodiments, the electric field strength on the sample may be adjusted by adjusting the voltage to the control electrode. Data plot 1210 illustrates a comparison of BSE collection efficiency of eight segments for BSEs having a specific energy and a specific emission angle. For example, applying a voltage of 3 kV to the control electrode may enhance the BSE collection efficiency of outer segments (e.g., segments 5 and 6) of a segmented BSE detector and substantially maintain the peak detected BSE energy level, illustrated in data plot 1220, and energy width distribution of BSEs detected by the segments of a segmented BSE detector, illustrated in data plot 1230.

In some embodiments, a higher voltage applied to the control electrode may increase the BSE collection efficiency for outer segments (e.g., segments 5 and 6) and decrease the BSE collection efficiency for inner segments (e.g., segments 1-4). A higher voltage applied to the control electrode may influence the path of low energy BSEs closer to the primary optical axis such that the BSEs are deflected towards the primary optical axis and may escape through the central opening of the BSE detector, thereby causing a decrease in the BSE collection efficiency. For the high energy BSEs, the higher voltage applied to the control electrode may deflect the BSEs to be detected by the BSE detector, thereby causing an increase in the BSE collection efficiency of outer segments of the BSE detector. In the context of this disclosure, outer segments refer to the segments of a segmented BSE detector that are located further from the primary optical axis at a larger off-axis distance, and inner segments refer to the segments located closer to the primary optical axis at a shorter off-axis distance. In some embodiments, as an example, segments 1, 2, 3, and 4 may comprise inner segments and segments 5, 6, 7, and 8 may comprise the outer segments.

As illustrated in data plot 1220, the peak energy for each segment may be adjusted based on the voltage signal applied to the control electrode. The adjustability of peak energy by adjusting the control electrode voltage may improve the image contrast for specific depths of the sample, thereby enhancing the accuracy of defect inspection or feature metrology.

In some embodiments, the electric field strength on the sample may be adjusted by adjusting the extraction voltage. In this context, extraction voltage refers to the potential difference between the sample and a polepiece of the objective lens. As an example, if the polepiece of objective lens and the sample are applied the same voltage, the potential difference and therefore the extraction voltage between them is zero. In other words, the objective lens and the sample are equipotential. If the voltage applied to the sample is higher than the voltage applied to the polepiece of the objective lens, then the sample is biased positive relative to the objective lens, and may increase the electric field strength between them, thereby extracting or “pushing” more electrons out of the sample.

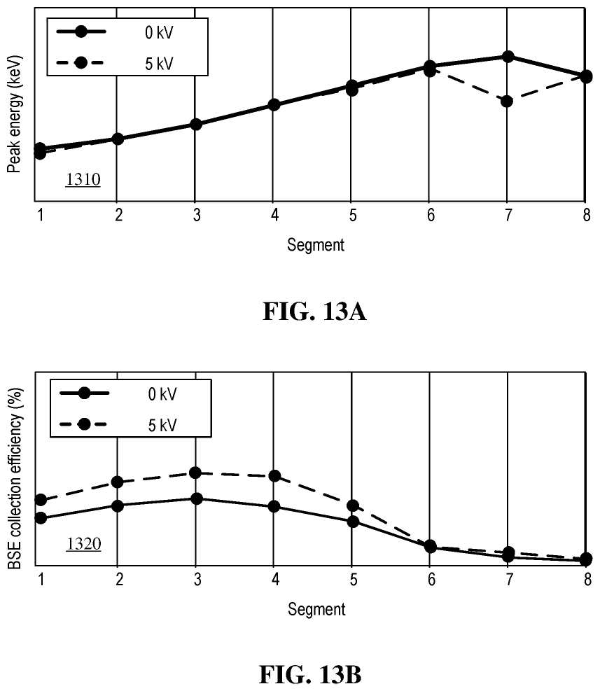

In some embodiments, the extraction voltage may be adjusted to adjust the peak BSE energy detection by a segment of a segmented BSE detector. Data plot 1310 of FIG. 13A shows a comparison of peak BSE energy detected by each segment of a segmented BSE detector for two different extraction voltages, 0 and 5 kV. As illustrated, the peak energy of BSE detected by segments 1 and 7 is different (e.g., lower peak energy for higher extraction electric fields) at an extraction voltage of 5 kV in comparison to the peak energy of BSE detected when the extraction voltage is 0 kV. The higher peak BSE energy detected for one or more segments of the BSE detector may be beneficial for improving the image contrast at a certain depth for defect inspection or metrology applications. Although not illustrated, the width of energy distribution of BSEs detected by each segment may also be adjusted by adjusting the extraction voltage, as appropriate.

Reference is now made to FIG. 13B, which illustrates a data plot of simulated values of BSE collection efficiency for each segment of a BSE detector for two different extraction voltages, 0 and 5 kV. A stronger extraction voltage, for example, 5 kV or more, may improve the BSE collection efficiency for each segment of the BSE detector. The enhanced BSE collection efficiency may be beneficial for improving the signal-to-noise (SNR) ratio and to improve the detector gain. The detector gain is proportional to the energy of the electrons that it receives, and therefore, when the voltage difference between the objective lens and the sample is higher, the electrons emitted from the surface of the sample have higher kinetic energy, resulting in better detector gain.

In some embodiments, the magnetic field strength of objective lens may be adjusted to adjust the BSE collection efficiency of a segment of a segmented BSE detector (e.g., BSE detector 713-1 of FIGS. 7A-7D). Adjusting the magnetic field strength of objective lens may include adjusting the excitation of objective lens. In some embodiments, the magnetic field strength of objective lens may be expressed as Ampere-Turns (AT), which is a unit of magnetomotive force (MMF), represented by a direct current of one Ampere flowing in a single turn loop in a vacuum. As an example, a current of 2 Amps flowing through a coil of 10 turns may produce an MMF of 20 AT.

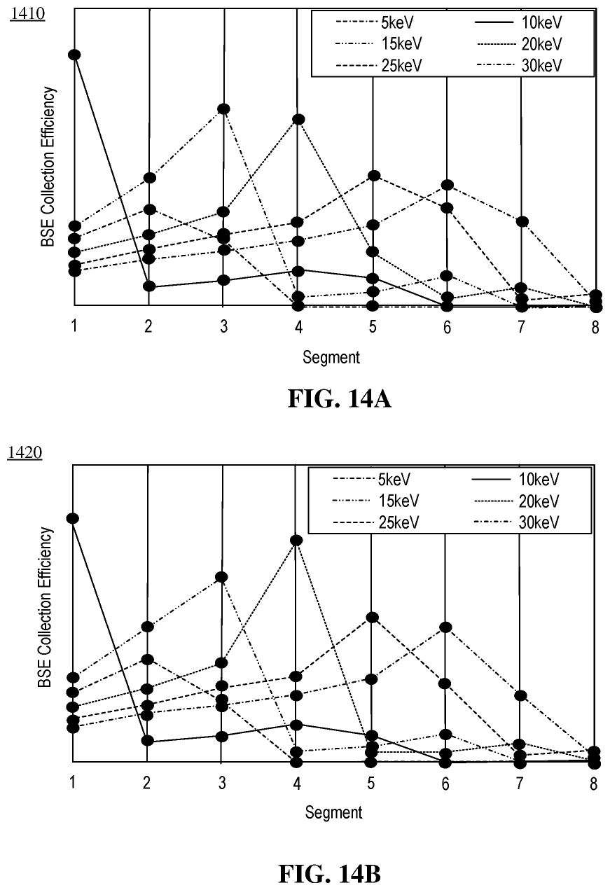

FIGS. 14A and 14B illustrate the relationship between the BSE collection efficiency for each segment of a segmented BSE detector based on the objective lens magnetic field strength, consistent with embodiments of the present disclosure. Data plot 1410 of FIG. 14A represents the BSE collection efficiency of eight segments of a segmented BSE detector, when the magnetic field strength of the objective lens is 3193 AT, a nominal height of the detector, a landing energy of 30 keV, and no electric field on the surface of the sample. In comparison, data plot 1420 of FIG. 14B, represents the BSE collection efficiency of eight segments of a segmented BSE detector, when the magnetic field strength of the objective lens is higher, approximately 3222 AT. For example, the BSE collection efficiency of segment 4 for a 20 keV BSE may be higher compared to the collection efficiency of segment 3 when the magnetic field strength of the objective lens is higher, as illustrated in data plot 1420 of FIG. 14B.

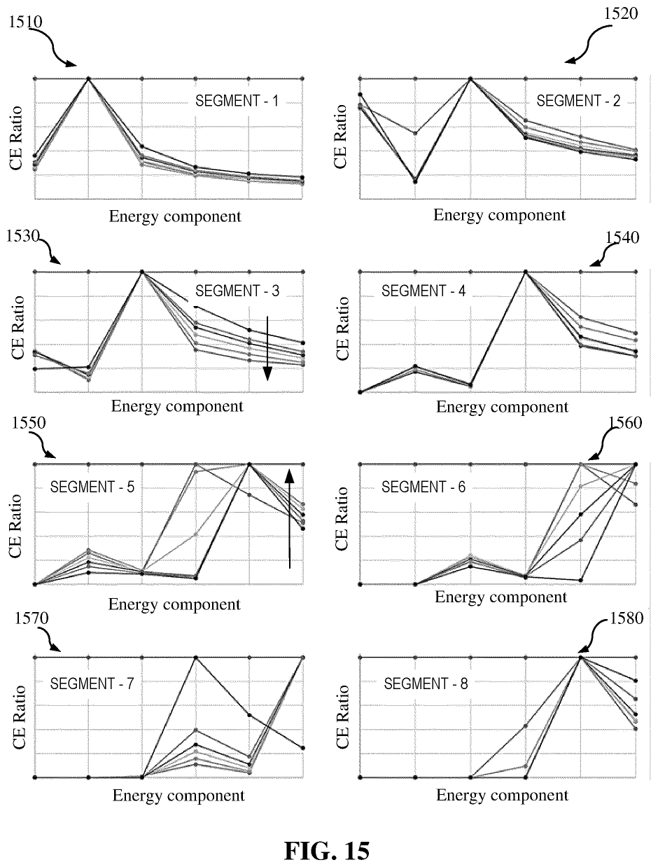

Reference is now made to FIG. 15, which further illustrates the impact of adjusting magnetic field strength of the objective lens on BSE collection efficiency of segments of a segmented BSE detector, consistent with embodiments of the present disclosure. A segmented BSE detector, as referred to in FIG. 15 may refer to an eight-segment BSE detector, such as BSE detector 713-1 of FIGS. 7A-7D. In FIG. 15, each sub-figure corresponds to an individual segment of the eight-segment BSE detector. As such, sub-figure 1510 corresponds to segment 1 of a BSE detector, sub-figure 1520 corresponds to segment 2 of a BSE detector, sub-figure 1530 corresponds to segment 3 of a BSE detector, sub-figure 1540 corresponds to segment 4 of a BSE detector, sub-figure 1550 corresponds to segment 5 of a BSE detector, sub-figure 1560 corresponds to segment 6 of a BSE detector, sub-figure 1570 corresponds to segment 7 of a BSE detector, and sub-figure 1580 corresponds to segment 8 of a BSE detector.

With reference to FIG. 15, each sub-figure (1510-1580) shows the relationship between different BSE energy components and their corresponding collection efficiency (CE) with respect to the maximum CE among a specific energy range. In that regard, a CE ratio of 100% indicates that the energy component has the highest collection efficiency in that segment. Further, in each sub-figure (1510-1580), an individual curve represents the change in collection efficiency for each segment at a specific objective lens excitation to generate a specific magnetic field. Because the strength of the magnetic field may impact the BSE energy or spatial distribution on the BSE detector, different curves behave differently.

As shown, each sub-figure of FIG. 15 represents the BSE collection efficiency for an individual segment for a range of magnetic field strength values, ranging from 0 AT to 3293 AT. At 0 AT, indicating that there is no magnetic field from the objective lens, all the energy components of the BSEs emitting from the sample may travel along the same electron trajectory, and therefore, the collection efficiency (CE) may be substantially similar or same for each energy component. This is represented by the data points at 100% CE ratio on the y-axis of each sub-figure. A nominal excitation of the objective lens may refer to the excitation of the objective lens such that the magnetic field generated cause the primary electron beam to focus on the surface of the sample. Objective lens excitations outside of the nominal range of excitation may indicate that the primary electron beam is either underfocused or overfocused.

Further, if the collection efficiency for an energy component is much higher than the other energy components, the achievable image contrast may be high. In other words, if the difference between collection efficiency of an energy component and other components is higher, the image contrast may be higher. In some embodiments, adjusting the magnetic field of the objective lens may allow adjusting the collection efficiency for one or more individual energy components, which may be used to further enhance the image contrast.

As illustrated in each sub-figure, each curve represents the change in BSE collection efficiency for individual segments for a specific objective lens excitation. In some embodiments, the objective lens excitation, and therefore, the magnetic field strength may be adjusted in intervals of 10 AT or more, 20 AT or more, 50 AT or more, 100 AT or more, or any appropriate range to determine the maximum difference between BSE collection efficiencies for the segments such that the image contrast may be optimized, and the energy-filtering resolution may be enhanced.

As an example, in sub-figure 1530, decreasing the objective excitation (represented by the arrow pointing down) such that the magnetic field strength is lower than the nominal excitation, may enhance the difference in collection efficiency between segment 3 and other segments. This may indicate that reducing the magnetic field strength may enable capturing images associated with a specific depth region of the sample, with higher contrast. In contrast, in sub-figure 1550, increasing the objective excitation (represented by the arrow pointing up) such that the magnetic field strength is higher than the nominal excitation, may enhance the difference in collection efficiency between segment 5 and other segments. This may indicate that increasing the magnetic field strength may enable capturing images associated with a specific depth region of the sample, with higher contrast. In some embodiments, controller 50 may be configured to adjust the objective lens excitation to enable adjusting the magnetic field strength, thereby enabling capturing images with better contrast and high accuracy metrology.

In some embodiments, an adjustment of the magnetic field of objective lens may enhance the image contrast, but it may change the focus of the primary charged-particle beam, such as a primary electron beam, traversing the path toward the sample. Adjusting the magnetic field of objective lens may include reducing the magnetic field or increasing the magnetic field, based on a desired BSE collection efficiency for an individual segment of a segmented BSE detector, thereby allowing a user to select a range of desired BSE energy originating from a certain depth of the sample and further to optimize the contrast of images generated from the detected BSEs. However, the advantages of better image contrast gained by adjusting the magnetic field of the objective lens may be significantly compromised if the adjustment of magnetic field causes the primary charged-particle beam to lose its focus. Therefore, it may be desirable to compensate the focus change introduced by the adjustment in magnetic field, to maintain high image contrast and high resolution.

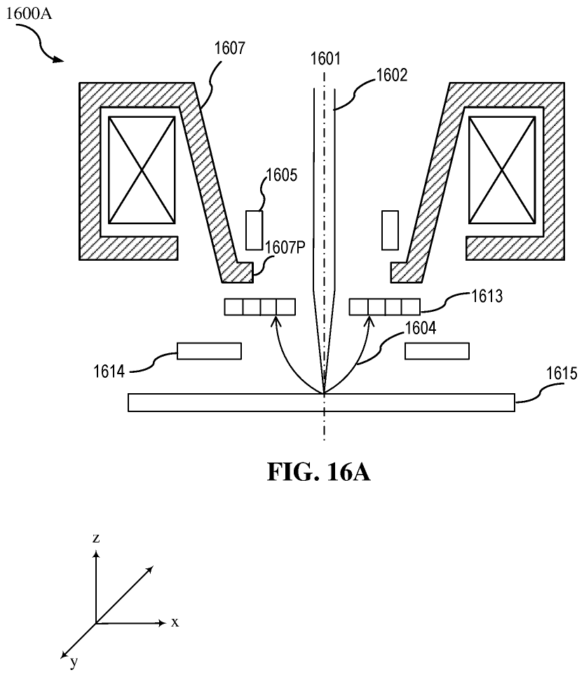

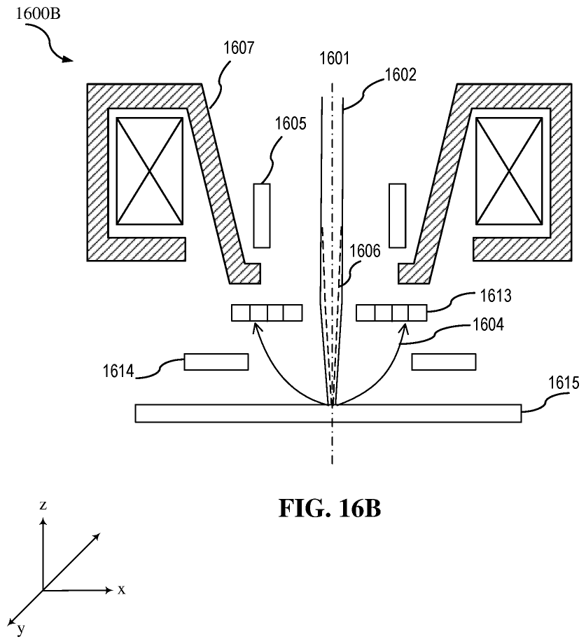

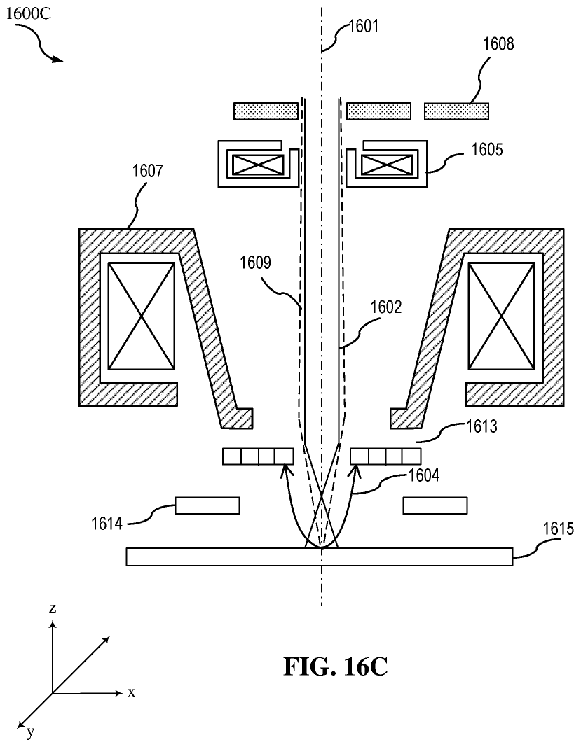

Reference is now made to FIG. 16A, which illustrates a schematic diagram of an exemplary charged-particle beam apparatus 1600A, consistent with embodiments of the present disclosure. In comparison with apparatus 400, apparatus 1600A may additionally include a focus compensation lens 1605 configured to compensate the change in focus of a primary charged-particle beam 1602 along a primary optical axis 1601. The change in focus of primary charged-particle beam 1602 may be caused due to, among other things, the change in magnetic field of objective lens 1607 to enhance the BSE collection efficiency of an individual segment of a segmented BSE detector 1613.

In some embodiments, focus compensation lens 1605 may be implemented by one or more deflectors (e.g., primary electron beam deflector 308, 309, 310, or 311 of FIG. 3) of a scanning deflection unit or a beam manipulator assembly. In some embodiments, focus compensation lens 1605 may be formed by a deflector (e.g., deflector 311 of FIG. 3) closest to BSE detector 1613. In such a scenario, focus compensation lens 1605 may have the least impact on the overall magnification of the imaging system, while compensating for focus change caused by an adjustment in the magnetic field of objective lens 1607. In some embodiments, focus compensation lens 1605 may be located immediately upstream of polepiece 1607P of objective lens 1607. If focus compensation lens 1605 is formed by the deflector closest to polepiece 1607P of objective lens 1607, which has a smaller inner diameter, a stronger focusing power may be obtained by applying a lower voltage compared to other deflectors of the scanning deflection unit upstream from the deflector closest to polepiece 1607P of objective lens 1607. In some embodiments, focus compensation lens 1605 may be realized by applying a same potential on all the electrodes of a scanning deflector to form a lens field to focus the charged-particle beam passing through.

In some embodiments, beam scanning deflector 1605 may comprise a quadrupole, a hexapole, or an octupole arrangement. In some embodiments, focus compensation lens 1605 may be realized by applying a same potential on all the electrodes of a scanning deflector to form a lens field to focus the charged-particle beam passing through.

As illustrated in FIG. 16A, objective lens may be nominally excited such that primary charged-particle beam 1602 is focused on the surface of sample 1615. In such a scenario, focus compensation lens 1605 may be deactivated and may not function as a focus compensation lens.

In some embodiments, the magnetic field of objective lens 1607 may be reduced by decreasing the objective lens excitation to enhance the difference in collection efficiency between segments of BSE detector 1613, as shown in sub-figure 1530 of FIG. 15. If the magnetic field of objective lens 1607 is weaker, the primary charged-particle beam 1602 may be underfocused on the surface of sample 1615, as illustrated in FIG. 16B. In such a scenario, focus compensation lens 1605 may be activated to compensate the change in focus due to an adjustment of objective lens excitation and adjust the focus of primary charged-particle beam 1602 to form a focused primary charged-particle beam 1606.

In some embodiments, the magnetic field of objective lens 1607 may be increased by increasing the objective lens excitation to enhance the difference in collection efficiency between segments of BSE detector 1613, as shown in sub-figure 1550 of FIG. 15. If the magnetic field of objective lens 1607 is stronger than the nominal excitation, the primary charged-particle beam 1602 may be overfocused on the surface of sample 1615, as illustrated in FIG. 16C. In such a scenario, to compensate the change in focus, the focusing power of a condenser lens 1605 may be lowered to form a focus-compensated divergent primary charged-particle beam 1609, which may be then focused on the surface of sample 1615 by the stronger objective lens magnetic field. In some embodiments, lowering the focusing power of condenser lens 1605 may result in reduction of probe current of the divergent primary charged-particle beam 1609. To compensate for the reduction in probe current, a larger coulomb aperture from a coulomb aperture array 1608 may be used to allow a larger beam to pass through to condenser lens 1605.

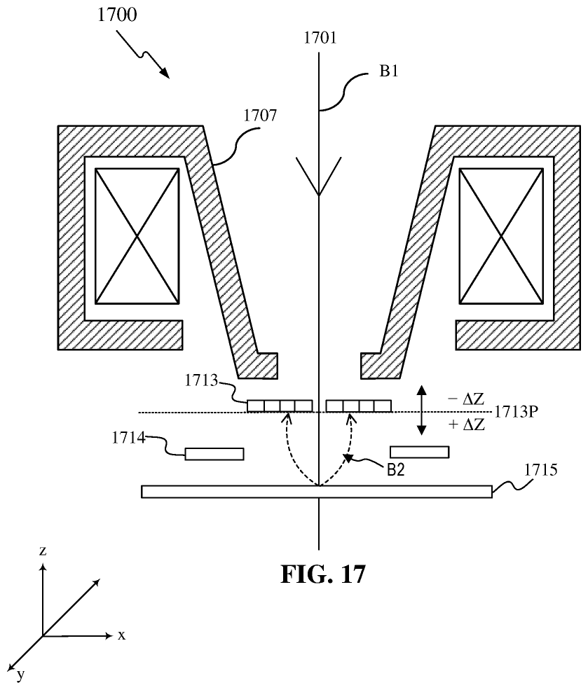

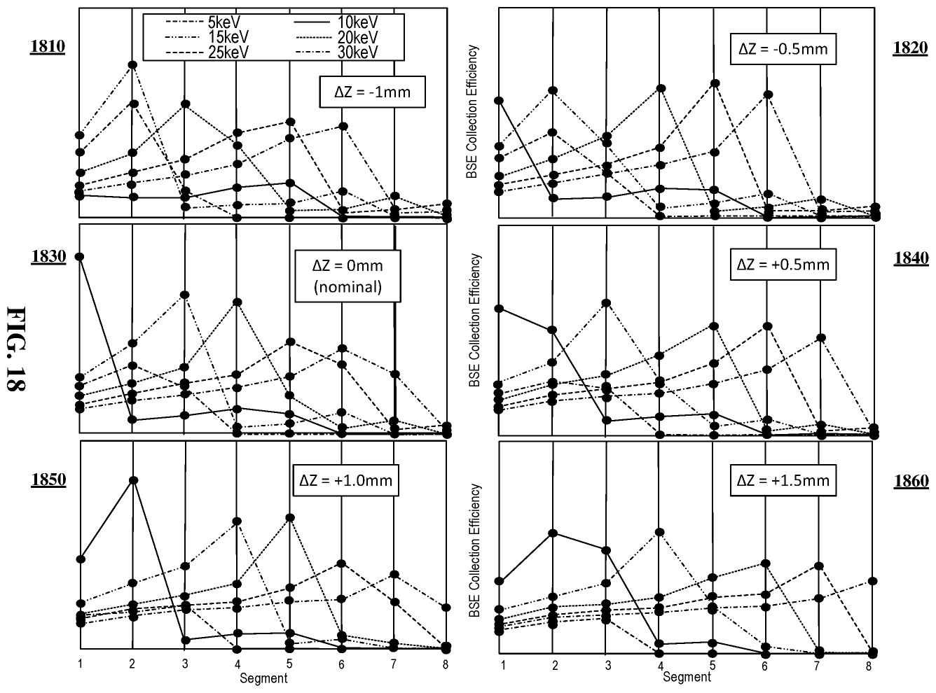

Reference is now made to FIG. 17, which illustrates a schematic diagram of an exemplary charged-particle beam apparatus 1700 comprising a segmented BSE detector, consistent with embodiments of the disclosure. Apparatus 1700 may include an objective lens 1707, a segmented BSE detector 1713 located at least substantially perpendicular to primary optical axis 1701, a control electrode 1714 located downstream from BSE detector 1713, and a sample 1715. In operation, a primary charged-particle beam B1 may be generated from a charged-particle source (not illustrated) and traversing down towards sample 1715. Upon interaction of the charged particles of primary charged-particle beam B1 with a region of sample 1715, signal charged particles forming a BSE beam B2 may be emitted from different depths of sample 1715 based on the interaction volume and collected at a detection surface of BSE detector 1713.

In some embodiments, a z-axis height of BSE detector 1713 may be referred to as the vertical distance between a top surface of sample 1713 and detection plane 1713P along which the detection surface of BSE detector 1713 extends. As illustrated in FIG. 17, the z-axis height of BSE detector 1713 may be adjustable within a range of positions with respect to the position of sample 1715. The z-axis position of BSE detector 1713 with the detection surface extending along detection plane 1713P may be referred to as the nominal position of BSE detector 1713. For the nominal position, ΔZ=0, where ΔZ is the difference in z-axis position with respect to the nominal position. If the z-axis position of BSE detector 1713 is adjusted such that its detection surface moves upstream from sample 1715 and closer to objective lens 1707, then ΔZ=[−distance]. If the z-axis position of BSE detector 1713 is adjusted such that its detection surface moves downstream closer to sample 1715, then ΔZ= [+distance].

FIG. 18 illustrates simulated graphical representations of the relationship between BSE collection efficiencies of individual segments of a segmented BSE detector and the BSE emission energy for a range of z-height positions of BSE detector, consistent with embodiments of present disclosure. Simulated data plot 1810 illustrates the BSE collection efficiency for individual segments for a z-height position of BSE detector ΔZ=−1 mm, simulated data plot 1820 illustrates the BSE collection efficiency for individual segments for a z-height position of BSE detector ΔZ=−0.5 mm, simulated data plot 1830 illustrates the BSE collection efficiency for individual segments for a z-height position of BSE detector ΔZ=0 mm (nominal position of BSE detector 1713), simulated data plot 1840 illustrates the BSE collection efficiency for individual segments for a z-height position of BSE detector ΔZ=+0.5 mm, simulated data plot 1850 illustrates the BSE collection efficiency for individual segments for a z-height position of BSE detector ΔZ=+1.0 mm, and simulated data plot 1860 illustrates the BSE collection efficiency for individual segments for a z-height position of BSE detector ΔZ=+1.5 mm. In some embodiments, the nominal position of BSE detector 1713 may be determined based on at least, but not limited to, the BSE collection efficiency at different segments of the BSE detector, the primary charged-particle beam resolution, objective lens magnetic field strength, high voltage stability between BSE detector and control electrode, among other things.

As illustrated in simulated data plots 1810-1860, the energy component of incoming BSE signals may be resolved based on the BSE collection efficiency of individual segments for a range of z-axis positions. In some embodiments, determining whether the energy components of incoming BSE signals are “resolved” may include determining if there is a distinctly identifiable energy component for which the BSE collection efficiency of an individual segment is the highest. In this context, the term “distinctly identifiable” energy component refers to an energy component for which the BSE collection efficiency is substantially higher than the BSE collection efficiency of other energy components such that the difference between the BSE collection efficiency of any two energy components is higher than a threshold. In some embodiments, the threshold may be predetermined or based on image contrast obtained as a result of the difference in BSE collection efficiency. For example, as shown in simulated data plot 1850, with BSE detector located at ΔZ=+1 mm, the BSE collection efficiency of segment 2 for an energy component of 10 keV is substantially higher than the other energy components, and therefore, the energy components may be resolved if the BSE detector is moved closer to sample 1715.

In some embodiments, determining whether the energy components of incoming BSE signals are resolved may include determining if the BSE collection efficiency for each individual segment is higher than a threshold BSE collection efficiency. In some embodiments, the threshold BSE collection efficiency may be a predetermined threshold efficiency such as 5%, 6%, 7%, 8%, 9%, 10%, 11%, 12%, 15%, or any appropriate BSE collection efficiency or range of BSE collection efficiencies. For example, as shown in simulated data plot 1820, with BSE detector 1713 located at ΔZ=−0.5 mm, the BSE collection efficiency of each segment for an energy component is at least above a threshold BSE collection efficiency of 10%.

In some embodiments, determining whether the energy components of incoming BSE signals are resolved may include determining if there are as many distinctly identifiable energy components as possible. For example, as shown in simulated data plot 1820, with BSE detector 1713 located at ΔZ=−0.5 mm, substantially all the energy components may be distinctly identifiable based on the BSE collection efficiency of each segment for a specific energy component.

In some embodiments, the z-height of a BSE detector may be optimized based on whether the energy components of incoming BSE signals are resolved. One or more factors discussed above with respect to determining whether the energy components are resolved may be used to optimize the z-height of a BSE detector.

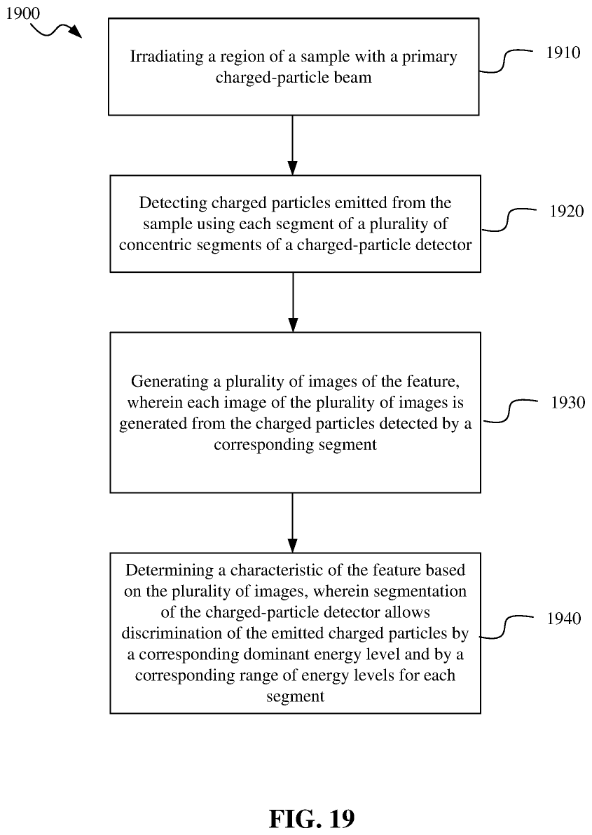

Reference is now made to FIG. 19, which illustrates a process flowchart representing an exemplary method 1900 of imaging a sample using a charged-particle beam apparatus such as apparatus 300 of FIG. 3, consistent with embodiments of the present disclosure.

In step 1910, a region of a sample comprising a feature is irradiated with a primary charged-particle beam. The primary charged-particle beam may comprise a primary electron beam. A controller (e.g., controller 50 of FIG. 1) is configured to apply a voltage signal to a cathode of an electron source configured to generate a plurality of primary electrons forming a primary electron beam. The electron source may be activated remotely, for example, by using software, an application, or a set of instructions for a processor of a controller to power the electron source through a control circuitry.

In step 1920, charged particles emitted from the sample upon interaction with the primary electron beam (e.g., beam 300B1 of FIG. 3) are detected using a charged-particle detector such as a BSE detector (e.g., BSE detector 713 of FIGS. 7A-7D). The BSE detector may comprise a plurality of concentric segments of a charged-particle sensitive material configured to detect the backscattered electrons emitted from the sample. Each segment of may be configured to collect the emitted charged particles having a range of energy levels and a dominant energy level from the range of energy levels.

The energy of a BSE may be correlated with the depth of the sample from which it is emitted. For example, higher energy BSEs may be emitted from a shallower region of the interaction volume of the sample and lower energy BSEs may be emitted from a deeper region of the interaction volume. Based on this correlation, the peak BSE energy detected by a segment of the BSE detector may correspond to a depth of the sample from which the BSE is emitted.

In step 1930, a plurality of images of the feature in the region of the sample is generated. Each segment of the plurality of concentric segments is configured to generate an image based on a total number of BSEs detected by the segment. The image generated by each segment may carry information associated with the feature at a certain depth. For example, a segment closer to the primary optical axis (e.g., primary optical axis 300-1 of FIG. 3) may detect BSEs having a lower peak energy compared to a segment farther from the primary optical axis which may detect BSEs having a higher peak energy. A lower peak energy BSE may indicate that the BSE was emitted from a deeper region of the sample, thus carrying information associated with the bottom portion of the feature. A higher peak energy BSE may indicate that the BSE was emitted from a shallower region of the sample, thus carrying information associated with the top portion of the feature.

In step 1940, a three-dimensional (3D) image may be formed from the plurality of images generated in step 1930. The 3D image formed may provide a high-quality image of the feature of interest in a single scan of the sample.

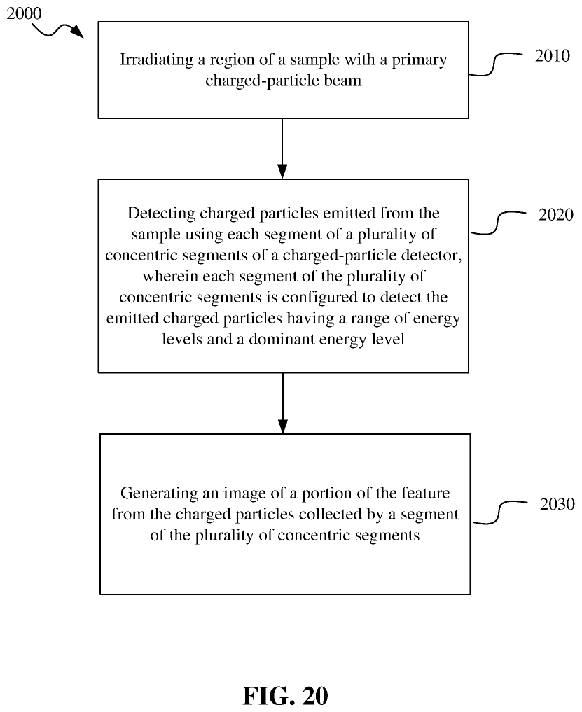

Reference is now made to FIG. 20, which illustrates a process flowchart representing an exemplary method 2000 of imaging a sample using a charged-particle beam apparatus such as apparatus 300 of FIG. 3, consistent with embodiments of the present disclosure.

In step 2010, a region of a sample comprising a feature is irradiated with a primary charged-particle beam. The primary charged-particle beam may comprise a primary electron beam. A controller (e.g., controller 50 of FIG. 1) is configured to apply a voltage signal to a cathode of an electron source configured to generate a plurality of primary electrons forming a primary electron beam. The electron source may be activated remotely, for example, by using software, an application, or a set of instructions for a processor of a controller to power the electron source through a control circuitry.

In step 2020, charged particles emitted from the sample upon interaction with the primary electron beam (e.g., beam 300B1 of FIG. 3) are detected using a charged-particle detector such as a BSE detector (e.g., BSE detector 713 of FIGS. 7A-7D). The BSE detector may comprise a plurality of concentric segments of a charged-particle sensitive material configured to detect the backscattered electrons emitted from the sample. Each segment may be configured to collect the emitted charged particles having a range of energy levels and a dominant energy level from the range of energy levels.

The energy of a BSE may be correlated with the depth of the sample from which it is emitted. For example, higher energy BSEs may be emitted from a shallower region of the interaction volume of the sample and lower energy BSEs may be emitted from a deeper region of the interaction volume. Based on this correlation, the peak BSE energy detected by a segment of the BSE detector may correspond to a depth of the sample from which the BSE is emitted.

In step 2030, an image (e.g., a two-dimensional image) of a desired portion of the feature may be generated from the BSEs detected by a segment of the plurality of concentric segments of the

BSE detector. For example, if the desired portion of the feature is the top portion, a high-contrast image may be generated from the BSEs detected by one or more segments farther from the primary optical axis (e.g., primary optical axis 300-1 of FIG. 3) configured to detect high energy BSEs. In some embodiments, a three-dimensional (3D) image may be formed using multiple high-contrast 2D images generated based on the BSEs detected by a segment having a desired peak energy and a desired range of energy levels.

It is to be appreciated that though the listed examples and apparatuses discuss single beam inspection systems, the disclosed systems and methods of energy discrimination of BSEs in a bottom BSE detector may be implemented in a multi-beam inspection system as well.

A non-transitory computer-readable medium may be provided that stores instructions for a processor of a controller (e.g., a central processing unit or electronic control unit that is configured to control a charged particle beam apparatus) for performing a method according to the exemplary flowcharts or other methods consistent with embodiments of the present disclosure. For example, the instructions stored in the non-transitory computer-readable medium may be executed by the circuitry of the controller for performing the methods in part or in their entireties. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

The embodiments may further be described using the following clauses:
1. A charged-particle beam apparatus, comprising:
a charged-particle source configured to generate primary charged particles, the primary charged particles forming a primary charged-particle beam along a primary optical axis; and
a charged-particle detector comprising a plurality of concentric segments of a charged-particle sensitive material configured to detect charged particles emitting from a sample after interaction of the primary charged-particle beam with the sample,
wherein each segment of the plurality of concentric segments is configured to collect the emitted charged particles having a range of energy levels and a dominant energy level.
2. The apparatus of clause 1, wherein segments of the plurality of concentric segments are separated by a charged-particle non-sensitive material.
3. The apparatus of any one of clauses 1 and 2, wherein the plurality of concentric segments is arranged concentrically around the primary optical axis.
4. The apparatus of any one of clauses 1-3, wherein the dominant energy level of a segment located at an off-axis distance smaller than a threshold off-axis distance is lower than the dominant energy level of a segment located at an off-axis distance larger than the threshold off-axis distance.
5. The apparatus of any one of clauses 1-4, wherein the charged-particle detector comprises a detection surface that is configured to directly receive the emitted charged particles from the sample, the detection surface comprising the charged-particle sensitive material of the plurality of concentric segments.
6. The apparatus of any one of clauses 1-5, wherein a z-axis position of the sample is adjustable along the primary optical axis, the adjustment of the z-axis position of the sample based on a landing energy of the primary charged particles.
7. The apparatus of clause 6, wherein an adjustment of the z-axis position of the sample with respect to the charged-particle detector enables influencing the dominant energy level for a segment of the plurality of concentric segments.
8. The apparatus of clause 7, wherein the adjustment of the z-axis position of the sample with respect to the charged-particle detector further enables influencing the range of energy levels detected by a segment of the charged-particle detector.
9. The apparatus of any one of clauses 7 and 8, wherein the adjustment of the z-axis position of the sample with respect to the charged-particle detector further enables influencing a uniformity of collection efficiency of emitted charged particles across the plurality of concentric segments.
10. The apparatus of clause 9, wherein the adjustment of the z-axis position of the sample with respect to the charged-particle detector increases a working distance between the sample and the charged-particle detector, and wherein the increase in the working distance enables an increase in the uniformity of collection efficiency of the emitted charged particles for the plurality of concentric segments.
11. The apparatus of clause 1, wherein a z-axis position of the charged-particle detector is adjustable along the primary optical axis.
12. The apparatus of clause 11, wherein an adjustment of the z-axis position of the charged-particle detector with respect to the sample enables influencing the dominant energy level for each segment of the plurality of concentric segments.
13. The apparatus of clause 12, wherein the adjustment of the z-axis position of the charged-particle detector with respect to the sample enables influencing a collection efficiency of emitted charged particles for the dominant energy level for each segment of the charged-particle detector.
14. The apparatus of clause 13, wherein the collection efficiency of emitted charged particles for the dominant energy level for each segment of the charged-particle detector is at least 10%.
15. The apparatus of clause 13, wherein the collection efficiency of emitted charged particles for the dominant energy level for each segment of the charged-particle detector is at least 15%.
16. A charged-particle beam apparatus, comprising:
a compound objective lens comprising a magnetic lens and an electrostatic lens, configured to focus a primary charged-particle beam on a surface of a sample; and
a charged-particle detector comprising a plurality of concentric segments of a charged-particle sensitive material configured to detect charged particles emitting from the sample upon interaction of the primary charged-particle beam with the sample,
wherein each segment of the plurality of concentric segments is configured to collect the emitted charged particles having a range of energy levels and a dominant energy level.
17. The apparatus of clause 16, wherein the compound objective lens is configured to provide an adjusted excitation signal to enable influencing a collection efficiency of the emitted charged particles of a segment of the plurality of concentric segments of the charged-particle detector.
18. The apparatus of clause 17, wherein an increase in the excitation signal of the compound objective lens is configured to cause an increase in the collection efficiency of the dominant energy level of the emitted charged particles with respect to the collection efficiency of a non-dominant energy level for a segment of the plurality of concentric segments of the charged-particle detector.
19. The apparatus of clause 17, wherein a decrease in the excitation signal of the compound objective lens is configured to cause an increase in the collection efficiency of the dominant energy level of the emitted charged particles with respect to the collection efficiency of a non-dominant energy level for a segment of the plurality of concentric segments of the charged-particle detector.
20. The apparatus of any one of clauses 17-19, wherein the adjustment of the excitation signal of the compound objective lens is configured to adjust a magnetic field strength, the magnetic field strength influencing a spatial distribution of the emitted charged particles on the plurality of concentric segments of the charged-particle detector.
21. The apparatus of any one of clauses 17-20, wherein the adjustment of the excitation signal of the compound objective lens is configured to enable influencing a contrast of an image generated from the charged particles detected by a segment of the plurality of concentric segments.
22. The apparatus of any one of clauses 17-21, wherein the excitation signal comprises a nominal excitation signal, and wherein the nominal excitation signal, when applied to the compound objective lens, is configured to enable the compound objective lens to focus the primary charged-particle beam on the sample.
23. The apparatus of any one of clauses 16-22, wherein the charged-particle detector is located between the compound objective lens and the sample.
24. The apparatus of any one of clauses 16-23, further comprising a beam scanning deflector configured to compensate a change in focus of the primary charged-particle beam to be incident on the surface of the sample.
25. The apparatus of clause 24, wherein the beam scanning deflector is located immediately upstream of a polepiece of the magnetic lens.
26. The apparatus of any one of clauses 24 and 25, wherein the beam scanning deflector comprises a plurality of electrodes, and wherein the plurality of electrodes is equipotential to form a lens field.
27. The apparatus of clause 26, wherein the beam scanning deflector is configured to receive an excitation signal to form the lens field, and wherein an adjustment of the excitation signal adjusts a compensation of the focus of the primary charged-particle beam.
28. The apparatus of clause 27, wherein excitation signal of the beam scanning deflector is deactivated when the nominal excitation signal is applied to the compound objective lens.
29. The apparatus of any one of clauses 24-28, wherein a voltage signal is applied to the beam scanning deflector when the excitation signal of the compound objective lens is lower than the nominal excitation signal.
30. The apparatus of clause 29, wherein the voltage signal applied to the beam scanning deflector is configured to enable the beam scanning deflector to focus the primary charged-particle beam on the surface of the sample.
31. The apparatus of any one of clauses 24-30, further comprising a condenser lens located upstream of the compound objective lens.
32. The apparatus of clause 31, wherein a focusing power of the condenser lens is adjusted to compensate a change in focus of the primary charged-particle beam when the excitation signal of the compound objective lens is higher than the nominal excitation. 33. The apparatus of clause 32, wherein the focusing power of the condenser lens is reduced to form a divergent primary charged-particle beam.
34. The apparatus of clause 33, further comprising an aperture array located upstream from the condenser lens, the aperture array comprising a plurality of apertures configured to adjust a beam current of the primary charged-particle beam based on a portion of the primary charged-particle beam allowed to pass through.
35. The apparatus of clause 34, wherein the portion of the primary charged-particle beam allowed to pass through compensates for a reduction in beam current caused by the reduced focusing power of the condenser lens.
36. A charged-particle beam apparatus, comprising:
a charged-particle source configured to generate primary charged particles, the primary charged particles forming a primary charged-particle beam along a primary optical axis to be incident on a sample;
a control electrode located immediately upstream from the sample and configured to influence an electrostatic field adjacent to the sample based on an applied voltage signal; and
a charged-particle detector comprising a plurality of concentric segments of a charged-particle sensitive material configured to detect charged particles emitting from the sample upon interaction of a primary charged-particle beam with the sample,
wherein each segment of the plurality of concentric segments is configured to collect the emitted charged particles having a range of energy levels and a dominant energy level.
37. The apparatus of clause 36, wherein the control electrode is located between the sample and the charged-particle detector.
38. The apparatus of any one of clauses 36 and 37, wherein the applied voltage signal to the control electrode enables influencing a collection efficiency of the emitted charged particles for each segment of the plurality of concentric segments of the charged-particle detector.
39. The apparatus of clause 38, wherein the applied voltage signal is configured to increase the collection efficiency of the emitted charged particles for a segment located at an off-axis distance more than a threshold off-axis distance.
40. The apparatus of clause 39, wherein the applied voltage signal is configured to decrease the collection efficiency of the emitted charged particles for a segment located at an off-axis distance less than the threshold off-axis distance.
41. The apparatus of any one of clauses 36-40, wherein an adjustment of the applied voltage signal to the control electrode enables influencing the dominant energy level of the emitted charged particles detected by a segment of the plurality of concentric segments of the charged-particle detector.
42. The apparatus of clause 41, wherein the adjustment of the applied voltage signal to the control electrode enables influencing the range of energy levels of the emitted charged particles detected by a segment of the plurality of concentric segments of the charged-particle detector.
43. The apparatus of any one of clauses 36-42, further comprising a compound objective lens located immediately upstream from the charged-particle detector, the compound objective lens comprising a magnetic lens and an electrostatic lens.
44. The apparatus of clause 43, wherein the compound objective lens is configured to receive a voltage signal to generate an electric field between the sample and the compound objective lens.
45. The apparatus of clause 44, wherein the generated electric field enables influencing a collection efficiency of the emitted charged particles for each segment of the plurality of concentric segments of the charged-particle detector.
46. The apparatus of clause 45, wherein the generated electric field enables an increase in the collection efficiency of the emitted charged particles for each segment of the plurality of concentric segments of the charged-particle detector.
47. The apparatus of any one of clauses 44-46, wherein the generated electric field further enables influencing the range of energy levels of the emitted charged particles detected by a segment of the plurality of concentric segments of the charged-particle detector.
48. The apparatus of clause 47, wherein the generated electric field further enables an increase in the range of energy levels of the emitted charged particles detected by the segment of the plurality of concentric segments of the charged-particle detector.
49. The apparatus of any one of clauses 44-46, wherein the generated electric field further enables influencing the dominant energy level of charged particles detected by a segment of the plurality of concentric segments of the charged-particle detector.
50. The apparatus of clause 49, wherein the generated electric field further enables an increase in the dominant energy level of charged particles detected by the segment of the plurality of concentric segments of the charged-particle detector.
51. The apparatus of clause 49, wherein the generated electric field further enables a decrease in the dominant energy level of charged particles detected by the segment of the plurality of concentric segments of the charged-particle detector.
52. A charged-particle detector for use in a charged-particle beam apparatus, the charged-particle detector comprising:
a plurality of concentric segments of a charged-particle sensitive material configured to detect charged particles emitting from a sample,
wherein each segment of the plurality of concentric segments is configured to detect the emitted charged particles having a range of energy levels and a corresponding dominant energy level.
53. The charged-particle detector of clause 52, wherein segments of the plurality of concentric segments are separated by a charged-particle non-sensitive material.
54. The charged-particle detector of any one of clauses 52 and 53, wherein the plurality of concentric segments is arranged concentrically around a primary optical axis of the charged-particle beam apparatus.
55. The charged-particle detector of any one of clauses 54, further comprising a detection surface configured to directly receive the emitted charged particles, the detection surface comprising the charged-particle sensitive material.
56. The charged-particle detector of clause 55, wherein the detection surface is disposed perpendicular to the primary optical axis.
57. The charged-particle detector of any one of clauses 52-56, wherein the corresponding dominant energy level of a segment located at an off-axis distance more than a threshold off-axis distance is higher than the corresponding dominant energy level of a segment located at an off-axis distance less than the threshold off-axis distance.
58. The charged-particle detector of any one of clauses 52-57, wherein each segment of the plurality of concentric segments is circular.
59. The charged-particle detector of any one of clauses 52-57, wherein each segment of the plurality of concentric segments is polygonal.
60. The charged-particle detector of any one of clauses 52-59, further comprising a central opening aligned with the primary optical axis and configured to allow the primary charged-particle beam to pass through.
61. The charged-particle detector of any one of clauses 52-60, wherein a width of each segment of the plurality of concentric segments is substantially similar.
62. The charged-particle detector of any one of clauses 52-61, wherein the emitted charged particles comprise backscattered electrons.
63. A method of imaging a sample, the method comprising:
irradiating a region of the sample with a primary charged-particle beam, the region comprising a feature;
detecting, using each segment of a plurality of concentric segments of a charged-particle detector, charged particles emitted from the region of the sample;
generating a plurality of images of the feature, wherein each image of the plurality of images is generated from the charged particles detected by a corresponding segment of the plurality of concentric segments of the charged-particle detector; and
determining a characteristic of the feature based on the plurality of images,
wherein each segment of the plurality of concentric segments is configured to detect the emitted charged particles having a range of energy levels and a dominant energy level.
64. The method of clause 63, wherein the range of energy levels of detected charged particles corresponds to a range of depths of the sample from which the charged particles are emitted.
65. The method of any one of clauses 63 and 64, wherein the dominant energy level of detected charged particles corresponds to a depth of the sample from which the charged particles are emitted.
66. The method of any one of clauses 63-65, wherein the plurality of images of the feature is generated simultaneously during a single scan of the region of the sample with the primary charged-particle beam.
67. The method of any one of clauses 63-66, wherein configuring each segment comprises adjusting a z-axis position of the sample along a primary optical axis of the primary charged-particle beam.
68. The method of clause 67, wherein adjusting the z-axis position of the sample enables influencing the dominant energy level detected by a segment of the charged-particle detector.
69. The method of any one of clauses 67 and 68, wherein adjusting the z-axis position of the sample further enables influencing the range of energy levels detected by a segment of the charged-particle detector.
70. The method of any one of clauses 67-69, wherein adjusting the z-axis position of the sample further enables influencing a uniformity of collection efficiency of the plurality of segments across the charged-particle detector.
71. The method of clause 70, wherein adjusting the z-axis position of the sample adjusts a working distance between the sample and the charged-particle detector, and wherein increasing the working distance enables increasing the uniformity of collection efficiency of the plurality of segments of the charged-particle detector.
72. The method of any one of clauses 63-71, wherein configuring each segment comprises adjusting a z-axis position of the charged-particle detector with respect to the sample.
73. The method of clause 72, wherein adjusting the z-axis position of the charged-particle detector with respect to the sample enables influencing the dominant energy level detected by each segment of the charged-particle detector.
74. The method of clause 72 and 73, wherein adjusting the z-axis position of the charged-particle detector with respect to the sample enables influencing a collection efficiency of emitted charged particles of the dominant energy level for each segment of the plurality of segments of the charged-particle detector.
75. The method of clause 63-74, wherein configuring each segment further comprises adjusting a magnetic field strength experienced by the emitted charged particles by adjusting an excitation signal of a compound objective lens, the compound objective lens comprising a magnetic lens and an electrostatic lens.
76. The method of clause 75, wherein adjusting the magnetic field strength enables influencing a spatial distribution of emitted charged particles incident on a detection surface of each segment of the charged-particle detector.
77. The method of any one of clauses 75 and 76, wherein adjusting the magnetic field strength enables influencing a collection efficiency of the dominant energy level of the emitted charged particles for each segment of the charged-particle detector.
78. The method of any one of clauses 75-77, wherein increasing the magnetic field strength enables increasing a collection efficiency of a non-dominant energy level of the emitted charged particles for a first segment of the plurality of segments of the charged-particle detector.
79. The method of clause 78, wherein decreasing the magnetic field strength enables increasing a collection efficiency of a non-dominant energy level of the emitted charged particles for a second segment of the plurality of segments of the charged-particle detector.
80. The method of any one of clauses 75-79, wherein adjusting the magnetic field strength enables influencing an image contrast of the generated plurality of images.
81. The method of any one of clauses 75-80, wherein adjusting the excitation signal comprises adjusting a voltage signal applied to the magnetic lens of the compound objective lens.
82. The method of any one of clauses 75-81, wherein configuring each segment further comprises adjusting an electric field between the sample and the compound objective lens by adjusting a voltage signal applied to the electrostatic lens of the compound objective lens.
83. The method of clause 82, wherein adjusting the electric field enables influencing a collection efficiency of the emitted charged particles for each segment of the plurality of concentric segments of the charged-particle detector.
84. The method of clause 83, wherein adjusting the electric field enables increasing the collection efficiency of the emitted charged particles for each segment of the plurality of concentric segments of the charged-particle detector.
85. The method of any one of clauses 82-84, wherein adjusting the electric field further enables influencing the range of energy levels of the emitted charged particles detected by a segment of the plurality of concentric segments of the charged-particle detector.
86. The method of clause 85, wherein adjusting the electric field further enables increasing the range of energy levels of the emitted charged particles detected by the segment of the plurality of concentric segments of the charged-particle detector.
87. The method of clause 82-86, wherein adjusting the electric field further enables influencing the dominant energy level of the emitted charged particles detected by a segment of the plurality of concentric segments of the charged-particle detector.
88. The method of clause 87, wherein adjusting the electric field further enables increasing the dominant energy level of the emitted charged particles detected by the segment of the plurality of concentric segments of the charged-particle detector.
89. The method of clause 87, wherein adjusting the electric field further enables decreasing the dominant energy level of the emitted charged particles detected by the segment of the plurality of concentric segments of the charged-particle detector.
90. The method of any one of clauses 75-81, further comprising compensating, using a beam scanning deflector, a change in focus of the primary charged-particle beam, the change in focus caused by the adjustment of the magnetic field strength of the compound objective lens.
91. The method of clause 90, wherein the beam scanning deflector comprises a plurality of electrodes, and wherein the plurality of electrodes is equipotential to form a lens field.
92. The method of any one of clauses 90 and 91, wherein adjusting an excitation signal of the beam scanning deflector enables adjusting the compensation of the change in focus of the primary charged-particle beam.
93. The method of clause 92, wherein adjusting the excitation signal of the beam scanning deflector comprises adjusting a voltage signal applied to the beam scanning deflector.
94. The method of any one of clauses 92-93, further comprising deactivating the excitation signal of the beam scanning deflector when the primary charged-particle beam is focused on the sample.
95. The method of any one of clauses 90-94, further comprising adjusting a focusing power of a condenser lens located upstream from the compound objective lens, when the excitation signal applied to the compound objective lens is higher than a nominal excitation signal.
96. The method of clause 95, wherein adjusting the focusing power comprises decreasing the focusing power of the condenser lens to enable forming a divergent primary charged-particle beam.
97. The method of clause 96, further comprising allowing the primary charged-particle beam to pass through an aperture of an aperture array located upstream from the condenser lens, the aperture configured to allow a portion of the primary charged-particle beam, wherein the allowed portion compensates for a reduced beam current of the divergent primary charged-particle beam.
98. The method of any one of clauses 90-97, wherein configuring each segment comprises adjusting an electrostatic field adjacent to the sample by applying a voltage signal to a control electrode located immediately upstream from the sample.
99. The method of clause 98, wherein adjusting the electrostatic field enables influencing a collection efficiency of the emitted charged particles for each segment of the plurality of concentric segments of the charged-particle detector.
100. The method of clause 99, wherein adjusting the electrostatic field enables increasing the collection efficiency of the emitted charged particles for a segment located at an off-axis distance more than a threshold off-axis distance.
101. The method of clause 100, wherein adjusting the electrostatic field enables decreasing the collection efficiency of the emitted charged particles for a segment located at an off-axis distance less than the threshold off-axis distance.
102. The method of any one of clauses 98-101, wherein adjusting the electrostatic field enables influencing the dominant energy level of the emitted charged particles detected by a segment of the plurality of concentric segments of the charged-particle detector.
103. The method of clause 102, wherein adjusting the electrostatic field enables influencing the range of energy levels of the emitted charged particles detected by a segment of the plurality of concentric segments of the charged-particle detector.
104. The method of any one of clauses 63-103, wherein determining the characteristic of the feature comprises:
forming a three-dimensional image of the feature from the plurality of images; and determining the characteristic from the three-dimensional image.
105. The method of any one of clauses 63-104, wherein the characteristic comprises an overlay, a side-wall angle, a critical dimension, or a depth profile of the feature.
106. A charged-particle beam apparatus, comprising:
a charged-particle source configured to generate primary charged particles, the primary charged particles forming a primary charged-particle beam along a primary optical axis;
a charged-particle detector comprising a plurality of segments concentric with the primary charged-particle beam and configured to detect charged particles emitted from the sample; and
a controller including circuitry configured to:
   irradiate a region of the sample comprising a feature, with the primary charged-particle beam;
   generate a plurality of images of the irradiated region, wherein each image of the plurality of images is generated from the charged particles detected by a corresponding segment of the charged-particle detector;
   determine a characteristic of the feature based on the plurality of images,
   wherein segmentation of the charged-particle detector allows discrimination of the emitted charged particles by a corresponding dominant energy level and by a corresponding range of energy levels for each segment.
107. The apparatus of clause 106, wherein segments of the plurality of concentric segments are separated by a charged-particle non-sensitive material.
108. The apparatus of any one of clauses 106 and 107, wherein the plurality of concentric segments is arranged concentrically around the primary optical axis.
109. The apparatus of any one of clauses 106-108, wherein the dominant energy level of a segment located at an off-axis distance smaller than a threshold off-axis distance is lower than the dominant energy level of a segment located at an off-axis distance larger than the threshold off-axis distance.
110. The apparatus of any one of clauses 106-109, wherein the charged-particle detector comprises a detection surface that is configured to directly receive the emitted charged particles from the sample, the detection surface comprising the charged-particle sensitive material of the plurality of concentric segments.
111. The apparatus of any one of clauses 106-110, wherein a z-axis position of the sample is adjustable along the primary optical axis, the adjustment of the z-axis position of the sample based on a landing energy of the primary charged particles.
112. The apparatus of clause 111, wherein an adjustment of the z-axis position of the sample with respect to the charged-particle detector enables influencing the dominant energy level for a segment of the plurality of concentric segments.
113. The apparatus of clause 112, wherein the adjustment of the z-axis position of the sample with respect to the charged-particle detector further enables influencing the range of energy levels detected by a segment of the charged-particle detector.
114. The apparatus of any one of clauses 112 and 113, wherein the adjustment of the z-axis position of the sample with respect to the charged-particle detector further enables influencing a uniformity of collection efficiency of emitted charged particles across the plurality of concentric segments.
115. The apparatus of clause 114, wherein the adjustment of the z-axis position of the sample with respect to the charged-particle detector increases a working distance between the sample and the charged-particle detector, and wherein the increase in the working distance enables an increase in the uniformity of collection efficiency of the emitted charged particles for the plurality of concentric segments.
116. The apparatus of clause 115, wherein a z-axis position of the charged-particle detector is adjustable along the primary optical axis.
117. The apparatus of clause 116, wherein an adjustment of the z-axis position of the charged-particle detector with respect to the sample enables influencing the dominant energy level for each segment of the plurality of concentric segments.
118. The apparatus of clause 117, wherein the adjustment of the z-axis position of the charged-particle detector with respect to the sample enables influencing a collection efficiency of emitted charged particles for the dominant energy level for each segment of the charged-particle detector.
119. The apparatus of clause 118, wherein the collection efficiency of emitted charged particles for the dominant energy level for each segment of the charged-particle detector is at least 10%.
120. The apparatus of clause 118, wherein the collection efficiency of emitted charged particles for the dominant energy level for each segment of the charged-particle detector is at least 15%.
121. The apparatus of any one of clauses 106-120, further comprising a compound objective lens comprising a magnetic lens and an electrostatic lens, configured to focus a primary charged-particle beam on a surface of a sample.
122. The apparatus of clause 121, wherein the compound objective lens is configured to provide an adjusted excitation signal to enable influencing a collection efficiency of the emitted charged particles of a segment of the plurality of concentric segments of the charged-particle detector.
123. The apparatus of clause 122, wherein an increase in the excitation signal of the compound objective lens is configured to cause an increase in the collection efficiency of the dominant energy level of the emitted charged particles with respect to the collection efficiency of a non-dominant energy level for a segment of the plurality of concentric segments of the charged-particle detector.
124. The apparatus of clause 122, wherein a decrease in the excitation signal of the compound objective lens is configured to cause an increase in the collection efficiency of the dominant energy level of the emitted charged particles with respect to the collection efficiency of a non-dominant energy level for a segment of the plurality of concentric segments of the charged-particle detector.
125. The apparatus of any one of clauses 122-124, wherein the adjustment of the excitation signal of the compound objective lens is configured to adjust a magnetic field strength, the magnetic field strength influencing a spatial distribution of the emitted charged particles on the plurality of concentric segments of the charged-particle detector.
126. The apparatus of any one of clauses 122-125, wherein the adjustment of the excitation signal of the compound objective lens is configured to enable influencing a contrast of an image generated from the charged particles detected by a segment of the plurality of concentric segments.
127. The apparatus of any one of clauses 122-126, wherein the excitation signal comprises a nominal excitation signal, and wherein the nominal excitation signal, when applied to the compound objective lens, is configured to enable the compound objective lens to focus the primary charged-particle beam on the sample.
128. The apparatus of any one of clauses 121-127, wherein the charged-particle detector is located between the compound objective lens and the sample.
129. The apparatus of any one of clauses 121-128, further comprising a beam scanning deflector configured to compensate a change in focus of the primary charged-particle beam to be incident on the surface of the sample.
130. The apparatus of clause 129, wherein the beam scanning deflector is located immediately upstream of a polepiece of the magnetic lens.
131. The apparatus of any one of clauses 129 and 130, wherein the beam scanning deflector comprises a plurality of electrodes, and wherein the plurality of electrodes is equipotential to form a lens field.
132. The apparatus of clause 131, wherein the beam scanning deflector is configured to receive an excitation signal to form the lens field, and wherein an adjustment of the excitation signal adjusts a compensation of the focus of the primary charged-particle beam.
133. The apparatus of clause 132, wherein excitation signal of the beam scanning deflector is deactivated when the nominal excitation signal is applied to the compound objective lens.
134. The apparatus of any one of clauses 129-133, wherein a voltage signal is applied to the beam scanning deflector when the excitation signal of the compound objective lens is lower than the nominal excitation signal.
135. The apparatus of clause 134, wherein the voltage signal applied to the beam scanning deflector is configured to enable the beam scanning deflector to focus the primary charged-particle beam on the surface of the sample.
136. The apparatus of any one of clauses 129-135, further comprising a condenser lens located upstream of the compound objective lens.
137. The apparatus of clause 136, wherein a focusing power of the condenser lens is adjusted to compensate a change in focus of the primary charged-particle beam when the excitation signal of the compound objective lens is higher than the nominal excitation.
138. The apparatus of clause 137, wherein the focusing power of the condenser lens is reduced to form a divergent primary charged-particle beam.
139. The apparatus of clause 138, further comprising an aperture array located upstream from the condenser lens, the aperture array comprising a plurality of apertures configured to adjust a beam current of the primary charged-particle beam based on a portion of the primary charged-particle beam allowed to pass through.
140. The apparatus of clause 139, wherein the portion of the primary charged-particle beam allowed to pass through compensates for a reduction in beam current caused by the reduced focusing power of the condenser lens.
141. The apparatus of any one of clauses 106-140, further comprising a control electrode located immediately upstream from the sample and configured to influence an electrostatic field adjacent to the sample based on an applied voltage signal.
142. The apparatus of clause 141, wherein the control electrode is located between the sample and the charged-particle detector.
143. The apparatus of any one of clauses 141 and 142, wherein the applied voltage signal to the control electrode enables influencing a collection efficiency of the emitted charged particles for each segment of the plurality of concentric segments of the charged-particle detector.
144. The apparatus of clause 143, wherein the applied voltage signal is configured to increase the collection efficiency of the emitted charged particles for a segment located at an off-axis distance more than a threshold off-axis distance.
145. The apparatus of clause 144, wherein the applied voltage signal is configured to decrease the collection efficiency of the emitted charged particles for a segment located at an off-axis distance less than the threshold off-axis distance.
146. The apparatus of any one of clauses 141-145, wherein an adjustment of the applied voltage signal to the control electrode enables influencing the dominant energy level of the emitted charged particles detected by a segment of the plurality of concentric segments of the charged-particle detector.
147. The apparatus of clause 146, wherein the adjustment of the applied voltage signal to the control electrode enables influencing the range of energy levels of the emitted charged particles detected by a segment of the plurality of concentric segments of the charged-particle detector.
148. A method of imaging a sample, the method comprising:
irradiating a region of the sample with a primary charged-particle beam, the region comprising a feature;
detecting charged particles emitted from the region of the sample using each segment of a plurality of concentric segments of a charged-particle detector,
   wherein each segment of the plurality of concentric segments is configured to detect the emitted charged particles having a range of energy levels and a dominant energy level; and
generating an image of a portion of the feature from the charged particles collected by a segment of the plurality of concentric segments.
149. The method of clause 148, wherein the range of energy levels of detected charged particles corresponds to a range of depths of the sample from which the charged particles are emitted.
150. The method of any one of clauses 148 and 149, wherein the dominant energy level of detected charged particles corresponds to a depth of the sample from which the charged particles are emitted.
151. The method of any one of clauses 148-150, wherein configuring each segment comprises adjusting a z-axis position of the sample along a primary optical axis of the primary charged-particle beam.
152. The method of clause 151, wherein adjusting the z-axis position of the sample enables influencing the dominant energy level detected by a segment of the charged-particle detector.
153. The method of any one of clauses 151 and 152, wherein adjusting the z-axis position of the sample further enables influencing the range of energy levels detected by a segment of the charged-particle detector.
154. The method of any one of clauses 151-153, wherein adjusting the z-axis position of the sample further enables influencing a uniformity of collection efficiency of the plurality of segments across the charged-particle detector.
155. The method of clause 154, wherein adjusting the z-axis position of the sample adjusts a working distance between the sample and the charged-particle detector, and wherein increasing the working distance enables increasing the uniformity of collection efficiency of the plurality of segments of the charged-particle detector.
156. The method of any one of clauses 151-155, wherein configuring each segment comprises adjusting a z-axis position of the charged-particle detector with respect to the sample.
157. The method of clause 156, wherein adjusting the z-axis position of the charged-particle detector with respect to the sample enables influencing the dominant energy level detected by each segment of the charged-particle detector.
158. The method of clause 156 and 157, wherein adjusting the z-axis position of the charged-particle detector with respect to the sample enables influencing a collection efficiency of emitted charged particles of the dominant energy level for each segment of the plurality of segments of the charged-particle detector.
159. The method of clause 148-158, wherein configuring each segment further comprises adjusting a magnetic field strength experienced by the emitted charged particles by adjusting an excitation signal of a compound objective lens, the compound objective lens comprising a magnetic lens and an electrostatic lens.
160. The method of clause 159, wherein adjusting the magnetic field strength enables influencing a spatial distribution of emitted charged particles incident on a detection surface of each segment of the charged-particle detector.
161. The method of any one of clauses 159 and 160, wherein adjusting the magnetic field strength enables influencing a collection efficiency of the dominant energy level of the emitted charged particles for each segment of the charged-particle detector.
162. The method of any one of clauses 159-161, wherein increasing the magnetic field strength enables increasing a collection efficiency of a non-dominant energy level of the emitted charged particles for a first segment of the plurality of segments of the charged-particle detector.
163. The method of clause 162, wherein decreasing the magnetic field strength enables increasing a collection efficiency of a non-dominant energy level of the emitted charged particles for a second segment of the plurality of segments of the charged-particle detector.
164. The method of any one of clauses 159-163, wherein adjusting the magnetic field strength enables influencing an image contrast of the generated plurality of images.
165. The method of any one of clauses 159-164, wherein adjusting the excitation signal comprises adjusting a voltage signal applied to the magnetic lens of the compound objective lens.
166. The method of any one of clauses 159-165, wherein configuring each segment further comprises adjusting an electric field between the sample and the compound objective lens by adjusting a voltage signal applied to the electrostatic lens of the compound objective lens.
167. The method of clause 166, wherein adjusting the electric field enables influencing a collection efficiency of the emitted charged particles for each segment of the plurality of concentric segments of the charged-particle detector.
168. The method of clause 167, wherein adjusting the electric field enables increasing the collection efficiency of the emitted charged particles for each segment of the plurality of concentric segments of the charged-particle detector.
169. The method of any one of clauses 166-168, wherein adjusting the electric field further enables influencing the range of energy levels of the emitted charged particles detected by a segment of the plurality of concentric segments of the charged-particle detector.
170. The method of clause 169, wherein adjusting the electric field further enables increasing the range of energy levels of the emitted charged particles detected by the segment of the plurality of concentric segments of the charged-particle detector.
171. The method of clause 166-170, wherein adjusting the electric field further enables influencing the dominant energy level of the emitted charged particles detected by a segment of the plurality of concentric segments of the charged-particle detector.
172. The method of clause 171, wherein adjusting the electric field further enables increasing the dominant energy level of the emitted charged particles detected by the segment of the plurality of concentric segments of the charged-particle detector.
173. The method of clause 171, wherein adjusting the electric field further enables decreasing the dominant energy level of the emitted charged particles detected by the segment of the plurality of concentric segments of the charged-particle detector.
174. The method of any one of clauses 159-164, further comprising compensating, using a beam scanning deflector, a change in focus of the primary charged-particle beam, the change in focus caused by the adjustment of the magnetic field strength of the compound objective lens.
175. The method of clause 174, wherein the beam scanning deflector comprises a plurality of electrodes, and wherein the plurality of electrodes is equipotential to form a lens field.
176. The method of any one of clauses 174 and 175, wherein adjusting an excitation signal of the beam scanning deflector enables adjusting the compensation of the change in focus of the primary charged-particle beam.
177. The method of clause 176, wherein adjusting the excitation signal of the beam scanning deflector comprises adjusting a voltage signal applied to the beam scanning deflector.
178. The method of any one of clauses 176-177, further comprising deactivating the excitation signal of the beam scanning deflector when the primary charged-particle beam is focused on the sample.
179. The method of any one of clauses 174-178, further comprising adjusting a focusing power of a condenser lens located upstream from the compound objective lens, when the excitation signal applied to the compound objective lens is higher than a nominal excitation signal.
180. The method of clause 179, wherein adjusting the focusing power comprises decreasing the focusing power of the condenser lens to enable forming a divergent primary charged-particle beam.
181. The method of clause 180, further comprising allowing the primary charged-particle beam to pass through an aperture of an aperture array located upstream from the condenser lens, the aperture configured to allow a portion of the primary charged-particle beam, wherein the allowed portion compensates for a reduced beam current of the divergent primary charged-particle beam.
182. The method of any one of clauses 174-181, wherein configuring each segment comprises adjusting an electrostatic field adjacent to the sample by applying a voltage signal to a control electrode located immediately upstream from the sample.
183. The method of clause 182, wherein adjusting the electrostatic field enables influencing a collection efficiency of the emitted charged particles for each segment of the plurality of concentric segments of the charged-particle detector.
184. The method of clause 183, wherein adjusting the electrostatic field enables increasing the collection efficiency of the emitted charged particles for a segment located at an off-axis distance more than a threshold off-axis distance.
185. The method of clause 184, wherein adjusting the electrostatic field enables decreasing the collection efficiency of the emitted charged particles for a segment located at an off-axis distance less than the threshold off-axis distance.
186. The method of any one of clauses 182-185, wherein adjusting the electrostatic field enables influencing the dominant energy level of the emitted charged particles detected by a segment of the plurality of concentric segments of the charged-particle detector.
187. The method of clause 186, wherein adjusting the electrostatic field enables influencing the range of energy levels of the emitted charged particles detected by a segment of the plurality of concentric segments of the charged-particle detector.
188. A non-transitory computer readable medium storing a set of instructions that is executable by one or more processors of a charged-particle beam apparatus to cause the charged-particle beam apparatus to perform a method, the method comprising:
activating a charged-particle source to generate primary charged particles, the primary charged particles forming a primary charged-particle beam along a primary optical axis; irradiating a region of the sample comprising a feature, with the primary charged-particle beam;
detecting charged particles emitted from the sample using a charged-particle detector comprising a plurality of segments concentric with the primary charged-particle beam; generating a plurality of images of the irradiated region, wherein each image of the plurality of images is generated from the charged particles detected by a corresponding segment of the charged-particle detector; and
determining a characteristic of the feature based on the plurality of images, wherein segmentation of the charged-particle detector allows discrimination of the emitted charged particles by a corresponding dominant energy level and by a corresponding range of energy levels for each segment.
189. The non-transitory computer readable medium of clause 188, wherein the range of energy levels of detected charged particles corresponds to a range of depths of the sample from which the charged particles are emitted.
190. The non-transitory computer readable medium of any one of clauses 188 and 189, wherein the dominant energy level of detected charged particles corresponds to a depth of the sample from which the charged particles are emitted.
191. The non-transitory computer readable medium of any one of clauses 188-190, wherein the set of instructions is executable by the one or more processors to cause the charged-particle beam apparatus to further perform generating the plurality of images simultaneously during a single scan of the region of the sample with the primary charged-particle beam.
192. The non-transitory computer readable medium of any one of clauses 188-191, wherein the set of instructions is executable by the one or more processors to cause the charged-particle beam apparatus to further perform configuring each segment, wherein configuring each segment comprises adjusting a z-axis position of the sample along a primary optical axis of the primary charged-particle beam.
193. The non-transitory computer readable medium of clause 192, wherein adjusting the z-axis position of the sample enables influencing the dominant energy level detected by a segment of the charged-particle detector.
194. The non-transitory computer readable medium of any one of clauses 192 and 193, wherein adjusting the z-axis position of the sample further enables influencing the range of energy levels detected by a segment of the charged-particle detector.
195. The non-transitory computer readable medium of any one of clauses 192-194, wherein adjusting the z-axis position of the sample further enables influencing a uniformity of collection efficiency of the plurality of segments across the charged-particle detector.
196. The non-transitory computer readable medium of clause 195, wherein adjusting the z-axis position of the sample adjusts a working distance between the sample and the charged-particle detector, and wherein increasing the working distance enables increasing the uniformity of collection efficiency of the plurality of segments of the charged-particle detector.
197. The non-transitory computer readable medium of any one of clauses 188-196, wherein the set of instructions is executable by the one or more processors to cause the charged-particle beam apparatus to further perform configuring each segment, wherein configuring each segment further comprises adjusting a z-axis position of the charged-particle detector with respect to the sample.
198. The non-transitory computer readable medium of clause 197, wherein adjusting the z-axis position of the charged-particle detector with respect to the sample enables influencing the dominant energy level detected by each segment of the charged-particle detector.
199. The non-transitory computer readable medium of clause 197 and 198, wherein adjusting the z-axis position of the charged-particle detector with respect to the sample enables influencing a collection efficiency of emitted charged particles of the dominant energy level for each segment of the plurality of segments of the charged-particle detector.
200. The non-transitory computer readable medium of clause 188-199, wherein the set of instructions is executable by the one or more processors to cause the charged-particle beam apparatus to further perform configuring each segment, wherein configuring each segment further comprises adjusting a magnetic field strength experienced by the emitted charged particles by adjusting an excitation signal of a compound objective lens, the compound objective lens comprising a magnetic lens and an electrostatic lens.
201. The non-transitory computer readable medium of clause 200, wherein adjusting the magnetic field strength enables influencing a spatial distribution of emitted charged particles incident on a detection surface of each segment of the charged-particle detector.
202. The non-transitory computer readable medium of any one of clauses 200 and 201, wherein adjusting the magnetic field strength enables influencing a collection efficiency of the dominant energy level of the emitted charged particles for each segment of the charged-particle detector.
203. The non-transitory computer readable medium of any one of clauses 200-202, wherein increasing the magnetic field strength enables increasing a collection efficiency of a non-dominant energy level of the emitted charged particles for a first segment of the plurality of segments of the charged-particle detector.
204. The non-transitory computer readable medium of clause 203, wherein decreasing the magnetic field strength enables increasing a collection efficiency of a non-dominant energy level of the emitted charged particles for a second segment of the plurality of segments of the charged-particle detector.
205. The non-transitory computer readable medium of any one of clauses 200-204, wherein adjusting the magnetic field strength enables influencing an image contrast of the generated plurality of images.
206. The non-transitory computer readable medium of any one of clauses 200-205, wherein the set of instructions is executable by the one or more processors to cause the charged-particle beam apparatus to further perform adjusting a voltage signal applied to the magnetic lens of the compound objective lens.
207. The non-transitory computer readable medium of any one of clauses 200-206, wherein the set of instructions is executable by the one or more processors to cause the charged-particle beam apparatus to further perform configuring each segment, wherein configuring each segment further comprises adjusting an electric field between the sample and the compound objective lens by adjusting a voltage signal applied to the electrostatic lens of the compound objective lens.
208. The non-transitory computer readable medium of clause 207, wherein adjusting the electric field enables influencing a collection efficiency of the emitted charged particles for each segment of the plurality of concentric segments of the charged-particle detector.
209. The non-transitory computer readable medium of clause 208, wherein adjusting the electric field enables increasing the collection efficiency of the emitted charged particles for each segment of the plurality of concentric segments of the charged-particle detector.
210. The non-transitory computer readable medium of any one of clauses 207-209, wherein adjusting the electric field further enables influencing the range of energy levels of the emitted charged particles detected by a segment of the plurality of concentric segments of the charged-particle detector.
211. The non-transitory computer readable medium of clause 210, wherein adjusting the electric field further enables increasing the range of energy levels of the emitted charged particles detected by the segment of the plurality of concentric segments of the charged-particle detector.
212. The non-transitory computer readable medium of any one of clauses 207-211, wherein adjusting the electric field further enables influencing the dominant energy level of the emitted charged particles detected by a segment of the plurality of concentric segments of the charged-particle detector.
213. The non-transitory computer readable medium of clause 212, wherein adjusting the electric field further enables increasing the dominant energy level of the emitted charged particles detected by the segment of the plurality of concentric segments of the charged-particle detector.
214. The non-transitory computer readable medium of clause 212, wherein adjusting the electric field further enables decreasing the dominant energy level of the emitted charged particles detected by the segment of the plurality of concentric segments of the charged-particle detector.
215. The non-transitory computer readable medium of any one of clauses 200-206, wherein the set of instructions is executable by the one or more processors to cause the charged-particle beam apparatus to further perform compensating, using a beam scanning deflector, a change in focus of the primary charged-particle beam, the change in focus caused by the adjustment of the magnetic field strength of the compound objective lens.
216. The non-transitory computer readable medium of clause 215, wherein the beam scanning deflector comprises a plurality of electrodes, and wherein the plurality of electrodes is equipotential to form a lens field.
217. The non-transitory computer readable medium of any one of clauses 215 and 216, wherein adjusting an excitation signal of the beam scanning deflector enables adjusting the compensation of the change in focus of the primary charged-particle beam.
218. The non-transitory computer readable medium of clause 217, wherein the set of instructions is executable by the one or more processors to cause the charged-particle beam apparatus to further perform adjusting the excitation signal of the beam scanning deflector, wherein adjusting the excitation signal of the beam scanning deflector comprises adjusting a voltage signal applied to the beam scanning deflector.
219. The non-transitory computer readable medium of any one of clauses 217-218, wherein the set of instructions is executable by the one or more processors to cause the charged-particle beam apparatus to further perform deactivating the excitation signal of the beam scanning deflector when the primary charged-particle beam is focused on the sample.
220. The non-transitory computer readable medium of any one of clauses 215-219, wherein the set of instructions is executable by the one or more processors to cause the charged-particle beam apparatus to further perform adjusting a focusing power of a condenser lens located upstream from the compound objective lens, when the excitation signal applied to the compound objective lens is higher than a nominal excitation signal.
221. The non-transitory computer readable medium of clause 220, wherein the set of instructions is executable by the one or more processors to cause the charged-particle beam apparatus to further perform decreasing the focusing power of the condenser lens to enable forming a divergent primary charged-particle beam.
222. The non-transitory computer readable medium of clause 221, wherein the set of instructions is executable by the one or more processors to cause the charged-particle beam apparatus to further perform allowing the primary charged-particle beam to pass through an aperture of an aperture array located upstream from the condenser lens, the aperture configured to allow a portion of the primary charged-particle beam, wherein the allowed portion compensates for a reduced beam current of the divergent primary charged-particle beam.
223. The non-transitory computer readable medium of any one of clauses 215-222 wherein the set of instructions is executable by the one or more processors to cause the charged-particle beam apparatus to further perform configuring each segment, and wherein configuring each segment comprises adjusting an electrostatic field adjacent to the sample by applying a voltage signal to a control electrode located immediately upstream from the sample.
224. The non-transitory computer readable medium of clause 223, wherein adjusting the electrostatic field enables influencing a collection efficiency of the emitted charged particles for each segment of the plurality of concentric segments of the charged-particle detector.
225. The non-transitory computer readable medium of clause 224, wherein adjusting the electrostatic field enables increasing the collection efficiency of the emitted charged particles for a segment located at an off-axis distance more than a threshold off-axis distance.
226. The non-transitory computer readable medium of clause 225, wherein adjusting the electrostatic field enables decreasing the collection efficiency of the emitted charged particles for a segment located at an off-axis distance less than the threshold off-axis distance.
227. The non-transitory computer readable medium of any one of clauses 223-226, wherein adjusting the electrostatic field enables influencing the dominant energy level of the emitted charged particles detected by a segment of the plurality of concentric segments of the charged-particle detector.
228. The non-transitory computer readable medium of clause 227, wherein adjusting the electrostatic field enables influencing the range of energy levels of the emitted charged particles detected by a segment of the plurality of concentric segments of the charged-particle detector.
229. The non-transitory computer readable medium of any one of clauses 188-228, wherein determining the characteristic of the feature comprises:
forming a three-dimensional image of the feature from the plurality of images; and determining the characteristic from the three-dimensional image.
230. The non-transitory computer readable medium of any one of clauses 188-229, wherein the characteristic comprises an overlay, a side-wall angle, a critical dimension, or a depth profile of the feature.
231. A non-transitory computer readable medium storing a set of instructions that is executable by one or more processors of a charged-particle beam apparatus to cause the charged-particle beam apparatus to perform a method, the method comprising:
activating a charged-particle source to generate primary charged particles, the primary charged particles forming a primary charged-particle beam along a primary optical axis; irradiating a region of the sample comprising a feature, with the primary charged-particle beam;
detecting charged particles emitted from the region of the sample using each segment of a plurality of concentric segments of a charged-particle detector,
   wherein each segment of the plurality of concentric segments is configured to detect the emitted charged particles having a range of energy levels and a dominant energy level; and generating an image of a portion of the feature from the charged particles collected by a segment of the plurality of concentric segments.
232. The non-transitory computer readable medium of clause 231, wherein the range of energy levels of detected charged particles corresponds to a range of depths of the sample from which the charged particles are emitted.
233. The non-transitory computer readable medium of any one of clauses 231 and 232, wherein the dominant energy level of detected charged particles corresponds to a depth of the sample from which the charged particles are emitted.
234. The non-transitory computer readable medium of any one of clauses 231-233, wherein the set of instructions is executable by the one or more processors to cause the charged-particle beam apparatus to further perform configuring each segment, and wherein configuring each segment comprises adjusting a z-axis position of the sample along a primary optical axis of the primary charged-particle beam.
235. The non-transitory computer readable medium of clause 234, wherein adjusting the z-axis position of the sample enables influencing the dominant energy level detected by a segment of the charged-particle detector.
236. The non-transitory computer readable medium of any one of clauses 234 and 235, wherein adjusting the z-axis position of the sample further enables influencing the range of energy levels detected by a segment of the charged-particle detector.
237. The non-transitory computer readable medium of any one of clauses 234-236, wherein adjusting the z-axis position of the sample further enables influencing a uniformity of collection efficiency of the plurality of segments across the charged-particle detector.
238. The non-transitory computer readable medium of clause 237, wherein adjusting the z-axis position of the sample adjusts a working distance between the sample and the charged-particle detector, and wherein increasing the working distance enables increasing the uniformity of collection efficiency of the plurality of segments of the charged-particle detector.
239. The non-transitory computer readable medium of any one of clauses 234-238, wherein the set of instructions is executable by the one or more processors to cause the charged-particle beam apparatus to further perform configuring each segment, and wherein configuring each segment further comprises adjusting a z-axis position of the charged-particle detector with respect to the sample.
240. The non-transitory computer readable medium of clause 239, wherein adjusting the z-axis position of the charged-particle detector with respect to the sample enables influencing the dominant energy level detected by each segment of the charged-particle detector.
241. The non-transitory computer readable medium of clause 239 and 240, wherein adjusting the z-axis position of the charged-particle detector with respect to the sample enables influencing a collection efficiency of emitted charged particles of the dominant energy level for each segment of the plurality of segments of the charged-particle detector.
242. The non-transitory computer readable medium of any one of clauses 231-241, wherein the set of instructions is executable by the one or more processors to cause the charged-particle beam apparatus to further perform configuring each segment, and wherein configuring each segment further comprises adjusting a magnetic field strength experienced by the emitted charged particles by adjusting an excitation signal of a compound objective lens, the compound objective lens comprising a magnetic lens and an electrostatic lens.
243. The non-transitory computer readable medium of clause 242, wherein adjusting the magnetic field strength enables influencing a spatial distribution of emitted charged particles incident on a detection surface of each segment of the charged-particle detector.
244. The non-transitory computer readable medium of any one of clauses 242 and 243, wherein adjusting the magnetic field strength enables influencing a collection efficiency of the dominant energy level of the emitted charged particles for each segment of the charged-particle detector.
245. The non-transitory computer readable medium of any one of clauses 242-244, wherein increasing the magnetic field strength enables increasing a collection efficiency of a non-dominant energy level of the emitted charged particles for a first segment of the plurality of segments of the charged-particle detector.
246. The non-transitory computer readable medium of clause 245, wherein decreasing the magnetic field strength enables increasing a collection efficiency of a non-dominant energy level of the emitted charged particles for a second segment of the plurality of segments of the charged-particle detector.
247. The non-transitory computer readable medium of any one of clauses 242-246, wherein adjusting the magnetic field strength enables influencing an image contrast of the generated plurality of images.
248. The non-transitory computer readable medium of any one of clauses 242-247, wherein the set of instructions is executable by the one or more processors to cause the charged-particle beam apparatus to further perform adjusting the excitation signal, and wherein adjusting the excitation signal comprises adjusting a voltage signal applied to the magnetic lens of the compound objective lens.
249. The non-transitory computer readable medium of any one of clauses 242-248, wherein the set of instructions is executable by the one or more processors to cause the charged-particle beam apparatus to further perform configuring each segment, and wherein configuring each segment further comprises adjusting an electric field between the sample and the compound objective lens by adjusting a voltage signal applied to the electrostatic lens of the compound objective lens.
250. The non-transitory computer readable medium of clause 249, wherein adjusting the electric field enables influencing a collection efficiency of the emitted charged particles for each segment of the plurality of concentric segments of the charged-particle detector.
251. The non-transitory computer readable medium of clause 250, wherein adjusting the electric field enables increasing the collection efficiency of the emitted charged particles for each segment of the plurality of concentric segments of the charged-particle detector. 252. The non-transitory computer readable medium of any one of clauses 249-251, wherein adjusting the electric field further enables influencing the range of energy levels of the emitted charged particles detected by a segment of the plurality of concentric segments of the charged-particle detector.
253. The non-transitory computer readable medium of clause 252, wherein adjusting the electric field further enables increasing the range of energy levels of the emitted charged particles detected by the segment of the plurality of concentric segments of the charged-particle detector.
254. The non-transitory computer readable medium of any one of clauses 249-253, wherein adjusting the electric field further enables influencing the dominant energy level of the emitted charged particles detected by a segment of the plurality of concentric segments of the charged-particle detector.
255. The non-transitory computer readable medium of clause 254, wherein adjusting the electric field further enables increasing the dominant energy level of the emitted charged particles detected by the segment of the plurality of concentric segments of the charged-particle detector.
256. The non-transitory computer readable medium of clause 254, wherein adjusting the electric field further enables decreasing the dominant energy level of the emitted charged particles detected by the segment of the plurality of concentric segments of the charged-particle detector.
257. The non-transitory computer readable medium of any one of clauses 231-256, wherein the set of instructions is executable by the one or more processors to cause the charged-particle beam apparatus to further perform compensating, using a beam scanning deflector, a change in focus of the primary charged-particle beam, the change in focus caused by the adjustment of the magnetic field strength of the compound objective lens.
258. The non-transitory computer readable medium of clause 257, wherein the beam scanning deflector comprises a plurality of electrodes, and wherein the plurality of electrodes is equipotential to form a lens field.
259. The non-transitory computer readable medium of any one of clauses 257 and 258, wherein adjusting an excitation signal of the beam scanning deflector enables adjusting the compensation of the change in focus of the primary charged-particle beam.
260. The non-transitory computer readable medium of clause 259, wherein adjusting the excitation signal of the beam scanning deflector comprises adjusting a voltage signal applied to the beam scanning deflector.
261. The non-transitory computer readable medium of any one of clauses 259 and 260, wherein the set of instructions is executable by the one or more processors to cause the charged-particle beam apparatus to further perform deactivating the excitation signal of the beam scanning deflector when the primary charged-particle beam is focused on the sample.
262. The non-transitory computer readable medium of any one of clauses 257-261, wherein the set of instructions is executable by the one or more processors to cause the charged-particle beam apparatus to further perform adjusting a focusing power of a condenser lens located upstream from the compound objective lens, when the excitation signal applied to the compound objective lens is higher than a nominal excitation signal.
263. The non-transitory computer readable medium of clause 262, wherein the set of instructions is executable by the one or more processors to cause the charged-particle beam apparatus to further perform adjusting the focusing power, and wherein adjusting the focusing power comprises decreasing the focusing power of the condenser lens to enable forming a divergent primary charged-particle beam.
264. The non-transitory computer readable medium of clause 263, wherein the set of instructions is executable by the one or more processors to cause the charged-particle beam apparatus to further perform allowing the primary charged-particle beam to pass through an aperture of an aperture array located upstream from the condenser lens, the aperture configured to allow a portion of the primary charged-particle beam, wherein the allowed portion compensates for a reduced beam current of the divergent primary charged-particle beam.
265. The non-transitory computer readable medium of any one of clauses 257-264, wherein the set of instructions is executable by the one or more processors to cause the charged-particle beam apparatus to further perform configuring each segment, wherein configuring each segment further comprises adjusting an electrostatic field adjacent to the sample by applying a voltage signal to a control electrode located immediately upstream from the sample.
266. The non-transitory computer readable medium of clause 265, wherein adjusting the electrostatic field enables influencing a collection efficiency of the emitted charged particles for each segment of the plurality of concentric segments of the charged-particle detector.
267. The non-transitory computer readable medium of clause 266, wherein adjusting the electrostatic field enables increasing the collection efficiency of the emitted charged particles for a segment located at an off-axis distance more than a threshold off-axis distance.
268. The non-transitory computer readable medium of clause 267, wherein adjusting the electrostatic field enables decreasing the collection efficiency of the emitted charged particles for a segment located at an off-axis distance less than the threshold off-axis distance.
269. The non-transitory computer readable medium of any one of clauses 265-268, wherein adjusting the electrostatic field enables influencing the dominant energy level of the emitted charged particles detected by a segment of the plurality of concentric segments of the charged-particle detector.
270. The non-transitory computer readable medium of clause 269, wherein adjusting the electrostatic field enables influencing the range of energy levels of the emitted charged particles detected by a segment of the plurality of concentric segments of the charged-particle detector.

It will be appreciated that the embodiments of the present disclosure are not limited to the exact construction that has been described above and illustrated in the accompanying drawings, and that various modifications and changes can be made without departing from the scope thereof.

1. A charged-particle beam apparatus, comprising:
a charged-particle source configured to generate primary charged particles, the primary charged particles forming a primary charged-particle beam along a primary optical axis; and
a charged-particle detector comprising a plurality of concentric segments of a charged-particle sensitive material configured to detect charged particles emitting from a sample after interaction of the primary charged-particle beam with the sample,
wherein each segment of the plurality of concentric segments is configured to collect the emitted charged particles having a range of energy levels and a dominant energy level.

2. The apparatus of claim 1, wherein segments of the plurality of concentric segments are separated by a charged-particle non-sensitive material.

3. The apparatus of claim 1, wherein the plurality of concentric segments is arranged concentrically around the primary optical axis.

4. The apparatus of claim 1, wherein the dominant energy level of a segment located at an off-axis distance smaller than a threshold off-axis distance is lower than the dominant energy level of a segment located at an off-axis distance larger than the threshold off-axis distance.

5. The apparatus of claim 1, wherein the charged-particle detector comprises a detection surface that is configured to directly receive the emitted charged particles from the sample, the detection surface comprising the charged-particle sensitive material of the plurality of concentric segments.

6. The apparatus of claim 1, wherein a z-axis position of the sample is adjustable along the primary optical axis, the adjustment of the z-axis position of the sample based on a landing energy of the primary charged particles.

7. The apparatus of claim 6, wherein an adjustment of the z-axis position of the sample with respect to the charged-particle detector enables influencing the dominant energy level for a segment of the plurality of concentric segments.

8. The apparatus of claim 7, wherein the adjustment of the z-axis position of the sample with respect to the charged-particle detector further enables influencing the range of energy levels detected by a segment of the charged-particle detector.

9. The apparatus of claim 7, wherein the adjustment of the z-axis position of the sample with respect to the charged-particle detector further enables influencing a uniformity of collection efficiency of emitted charged particles across the plurality of concentric segments.

10. The apparatus of claim 9, wherein the adjustment of the z-axis position of the sample with respect to the charged-particle detector increases a working distance between the sample and the charged-particle detector, and wherein the increase in the working distance enables an increase in the uniformity of collection efficiency of the emitted charged particles for the plurality of concentric segments.

11. The apparatus of claim 1, wherein a z-axis position of the charged-particle detector is adjustable along the primary optical axis.

12. The apparatus of claim 11, wherein an adjustment of the z-axis position of the charged-particle detector with respect to the sample enables influencing the dominant energy level for each segment of the plurality of concentric segments.

13. The apparatus of claim 12, wherein the adjustment of the z-axis position of the charged-particle detector with respect to the sample enables influencing a collection efficiency of emitted charged particles for the dominant energy level for each segment of the charged-particle detector.

14. The apparatus of claim 13, wherein the collection efficiency of emitted charged particles for the dominant energy level for each segment of the charged-particle detector is at least 10%.

15. A non-transitory computer readable medium storing a set of instructions that is executable by one or more processors of a charged-particle beam apparatus to cause the charged-particle beam apparatus to perform a method, the method comprising:
activating a charged-particle source to generate primary charged particles, the primary charged particles forming a primary charged-particle beam along a primary optical axis;
irradiating a region of a sample comprising a feature, with the primary charged-particle beam;
detecting charged particles emitted from the sample using a charged-particle detector comprising a plurality of segments concentric with the primary charged-particle beam;
generating a plurality of images of the irradiated region, wherein each image of the plurality of images is generated from the charged particles detected by a corresponding segment of the charged-particle detector; and
determining a characteristic of the feature based on the plurality of images, wherein segmentation of the charged-particle detector allows discrimination of the emitted charged particles by a corresponding dominant energy level and by a corresponding range of energy levels for each segment.

16. The apparatus of claim 13, wherein the collection efficiency of emitted charged particles for the dominant energy level for each segment of the charged-particle detector is at least 15%.

17. A charged-particle detector for use in a charged-particle beam apparatus, the charged-particle detector comprising:
a plurality of concentric segments of a charged-particle sensitive material configured to detect charged particles emitting from a sample,
wherein each segment of the plurality of concentric segments is configured to detect the emitted charged particles having a range of energy levels and a corresponding dominant energy level.

18. The charged-particle detector of claim 17, wherein segments of the plurality of concentric segments are separated by a charged-particle non-sensitive material.

19. The charged-particle detector of claim 17, wherein the plurality of concentric segments is arranged concentrically around a primary optical axis of the charged-particle beam apparatus.

20. The charged-particle detector of claim 17, further comprising a detection surface configured to directly receive the emitted charged particles, the detection surface comprising the charged-particle sensitive material.
